(19) United States
(12) Patent Application Publication
(10) Pub. No.: US 2026/0044087 A1
(43) Pub. Date: Feb. 12, 2026

(54) SYSTEM AND METHOD FOR FABRICATING DIAGNOSTIC TARGETS

(71) Applicant: KLA Corporation, Milpitas, CA (US)

(72) Inventors: Rajeev Rajendran, San Francisco, CA (US); Farid Atry, San Jose, CA (US); Rui-Fang Shi, Cupertino, CA (US); Nicolas Juliano, Santa Clara, CA (US)

(21) Appl. No.: 19/297,983

(22) Filed: Aug. 12, 2025

Related U.S. Application Data
(60) Provisional application No. 63/681,956, filed on Aug. 12, 2024.

(51) Int. Cl. G03F 7/00; G03F 1/22; G03F 1/70

(52) U.S. Cl. CPC G03F 7/706845; G03F 1/22; G03F 1/70; G03F 7/70625

(57) ABSTRACT

A method may comprise fabricating a diagnostic sample using a fabrication process for fabricating a runtime sample, where the runtime sample can be configured to be used in a process tool, and where the diagnostic sample may include patterns designed to provide diagnostics of the process tool. The method can further comprise dicing the diagnostic sample into a plurality of diagnostic targets. Additionally, the method may comprise generating one or more quality metrics for the plurality of diagnostic targets. The diagnostic sample may be fabricated using the same fabrication process that can be used for fabricating the runtime sample, allowing the diagnostic targets to maintain material compatibility and quality standards. The dicing process may enable the creation of multiple diagnostic targets from a single diagnostic sample, providing cost-effective manufacturing. The quality metrics may ensure that the diagnostic targets meet specified requirements for use in process tool calibration and diagnostics.

### CROSS-REFERENCE TO RELATED APPLICATIONS

The present application claims the benefit under 35 U.S.C. § 119(e) of U.S. Provisional Application Ser. No. 63/681,956, filed Aug. 12, 2024, which is incorporated herein by reference in its entirety.

### TECHNICAL FIELD

The present disclosure relates to diagnostic target fabrication for process tool calibration, and more particularly to systems and methods for fabricating diagnostic targets by dicing diagnostic samples created using established fabrication processes to provide runtime diagnostics for inspection, metrology, and lithography tools.

### BACKGROUND

Actinic patterned mask inspection (APMI) tools are anchored on the principle of contiguous mask scanning across an extreme ultraviolet (EUV) field of view (FOV). In addition to achieving high static image quality, scanning systems such as APMI have the additional requirement of maintaining image performance over time (e.g., consistent performance within an inspected mask and repeatable inspection performance across multiple masks). This requirement translates to tight temporal control of critical image quality metrics. A necessary pre-requisite for control is system diagnostics of these critical imaging metrics. Run time diagnostics (RTD) of these metrics is hence the first step.

Among the myriad of system parameters that can impact EUV image quality, the critical parameters amenable to drifts and which have a direct impact on the actinic image quality include the EUV illumination pupil (EUV-P), EUV focus (EUV-F), and EUV wavefront error (EUV-WFE). For an RTD to be effective within an APMI tool, the measured system health parameters should be EUV specific, the measurements should be performed on targets having a known EUV imaging performance, the measurements should reflect the state of the system during inspection, the measurements should be periodically executed within inspections at frequencies determined by the system drift time scales, and the measurements should add minimal inspection overhead time.

Therefore, there is a need for effective methods, targets, and system architectures for RTD in inspection systems.

### SUMMARY

In some embodiments, a method is provided. The method may include fabricating a diagnostic sample using a fabrication process for fabricating a runtime sample, where the runtime sample is configured to be used in a process tool, and where the diagnostic sample includes patterns designed to provide diagnostics of the process tool. The method may include dicing the diagnostic sample into a plurality of diagnostic targets. The method may include generating one or more quality metrics for the plurality of diagnostic targets.

In some embodiments, the method may include filtering out any of the plurality of diagnostic targets that do not meet selected quality standards.

In some embodiments, the method may include placing at least one of the plurality of diagnostic targets proximate to the runtime sample in the process tool and generating diagnostic measurements of the process tool using the at least one of the plurality of diagnostic targets.

In some embodiments, the diagnostic measurements may be runtime diagnostics (RTD).

In some embodiments, the diagnostic sample may be an extreme ultraviolet (EUV) blank, and the process tool may be an EUV reticle inspection system.

In some embodiments, fabricating the patterns on the EUV blank to form the diagnostic sample may comply with standards for fabricating EUV reticles.

In some embodiments, the EUV blank may include an EUV reticle blank.

In some embodiments, the EUV reticle inspection system may include an actinic patterned mask inspection system.

In some embodiments, the method may include applying one or more protection layers to at least a portion of the patterns prior to dicing the diagnostic sample into the plurality of diagnostic targets.

In some embodiments, the method may include removing at least a portion of the one or more protection layers from at least some of the plurality of diagnostic targets after dicing.

In some embodiments, fabricating the diagnostic sample using the fabrication process used for fabricating the runtime sample may include fabricating patterned areas surrounded by margins, and dicing the diagnostic sample into the plurality of diagnostic targets may include dicing the diagnostic sample in the margins.

In some embodiments, the diagnostic sample may include a substrate with one or more layers, and at least a portion of the one or more layers may be stripped in the margins.

In some embodiments, the margins may include black border trenches surrounding the patterned areas.

In some embodiments, the plurality of diagnostic targets may include calibration chips.

In some embodiments, the plurality of diagnostic targets may include calibration bars.

In some embodiments, dicing the diagnostic sample may include at least one of blade dicing or laser dicing.

In some embodiments, dicing the diagnostic sample may include using fiducial marks to guide dicing alignment.

In some embodiments, the method may include post-dicing processing of the plurality of diagnostic targets, and the post-dicing processing may include at least one of polishing diced surfaces, chamfering edges, or cleaning the plurality of diagnostic targets.

In some embodiments, the one or more quality metrics may include at least one of dimensional tolerances, particle contamination limits, pattern fidelity requirements, and molecular cleanliness requirements.

In some embodiments, the plurality of diagnostic targets may have at least two sizes.

In some embodiments, the method may include packaging qualified diagnostic targets that meet the one or more quality metrics.

In some embodiments, the patterns may be configured to enable measurement of one or more imaging metrics including at least one of illumination pupil characteristics, focus characteristics, or wavefront error of the process tool.

In some embodiments, the patterns may include test structures for monitoring drift of at least one of the one or more imaging metrics.

In some embodiments, the process tool may include at least one of an inspection tool, a metrology tool, or a lithography tool.

In some embodiments, a system is provided. The system may include a fabrication tool configured to fabricate patterns on a diagnostic sample using a fabrication process for fabricating a runtime sample, where the runtime sample is configured to be used in a process tool, and where the diagnostic sample includes patterns designed to provide diagnostics of a process tool. The system may include a dicing tool configured to dice the diagnostic sample into a plurality of diagnostic targets. The system may include one or more qualification tools to generate one or more quality metrics for the plurality of diagnostic targets. The system may include the process tool including a stage configured to secure the runtime sample and at least one of the plurality of diagnostic targets and generate diagnostic measurements of the process tool using the at least one of the plurality of diagnostic targets.

In some embodiments, the system may include a controller including one or more processors configured to execute program instructions causing the one or more processors to filter out any of the plurality of diagnostic targets that do not meet selected quality standards.

In some embodiments, the sample may be an EUV blank, and the process tool may be an EUV reticle inspection system.

In some embodiments, the dicing tool may include at least one of a blade dicing tool or a laser dicing tool.

In some embodiments, the system may include one or more post-dicing processing tool configured to perform post-dicing processing of the diagnostic targets, and the post-dicing processing may include at least one of polishing diced surfaces, chamfering edges, or cleaning the diagnostic targets.

In some embodiments, the one or more quality metrics may include at least one of dimensional tolerances, particle contamination limits, pattern fidelity requirements, and molecular cleanliness requirements.

In some embodiments, the system may include a packaging tool configured to package qualified diagnostic targets that meet the one or more quality metrics.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF FIGURES

The numerous advantages of the disclosure may be better understood by those skilled in the art by reference to the accompanying figures.

FIG. 1 illustrates a block diagram of an inspection system, in accordance with one or more embodiments of the present disclosure.

FIG. 2A illustrates an isometric view of the inspection system of FIG. 1 with Actinic Patterned Mask Inspection (APMI) optical paths, in accordance with one or more embodiments of the present disclosure.

FIG. 2B illustrates an isometric view of the inspection system of FIG. 1 with APMI optical paths and a Reticle Transmission Diagnostic (RTD) field of view, in accordance with one or more embodiments of the present disclosure.

FIG. 3 illustrates a calibration chip manufacturing process from a patterned reticle, in accordance with one or more embodiments of the present disclosure.

FIG. 4 illustrates different views of a calibration bar structure, in accordance with one or more embodiments of the present disclosure.

FIG. 5 illustrates an inspection sequence diagram showing movement and imaging steps for the APMI system, in accordance with one or more embodiments of the present disclosure.

FIG. 6 illustrates an inspection sequence diagram showing a movement pattern for the inspection system with calibration targets, in accordance with one or more embodiments of the present disclosure.

FIGS. 7A-7E illustrate cross-sectional views of Extreme Ultraviolet (EUV) mask structures and patterns, in accordance with one or more embodiments of the present disclosure.

FIGS. 8A-8B illustrate side views of a stage assembly with diagnostic targets in different positions, in accordance with one or more embodiments of the present disclosure.

FIG. 9 illustrates a flowchart of a method for performing inspection system calibration, in accordance with one or more embodiments of the present disclosure.

FIG. 10 illustrates a block diagram of a system for manufacturing diagnostic targets, in accordance with one or more embodiments of the present disclosure.

FIG. 11 illustrates a flowchart showing EUV reticle fabrication processes and diagnostic target fabrication, in accordance with one or more embodiments of the present disclosure.

FIG. 12 illustrates a flowchart of a method for manufacturing diagnostic targets, in accordance with one or more embodiments of the present disclosure.

FIG. 13 illustrates two views of a diagnostic sample showing a dicing layout configuration, in accordance with one or more embodiments of the present disclosure.

FIG. 14 illustrates an isometric view of a diagnostic target layout with fiducial marks, in accordance with one or more embodiments of the present disclosure.

FIGS. 15A and 15B illustrate cross-sectional views of diagnostic targets with different protective configurations, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

The present disclosure provides effective run time diagnostics (RTD) for inspection systems, for instance lithography mask inspection systems. In a particular conceived example, the present disclosure provides RTD for actinic patterned mask inspection (APMI) tools. In embodiments, the measured system health parameters according to the present disclosure may be EUV specific and hence may be diagnosed at EUV wavelength (e.g., 13.5 nm). In embodiments, the measurements may be performed on auxiliary RTD specific targets having a predefined EUV stack having a known EUV performance. In embodiments, the present disclosure provides a holistic system-level EUV health check involving targets at the reticle plane. For accurate measurement, the EUV targets may provide adequate reflectivity, contrast, and imaging performance at EUV wavelength. In embodiments, the EUV targets may emulate the interaction of EUV light with the EUV stack (e.g., multilayer and absorber). In embodiments, the measurements may reflect the system state during inspection by utilizing inspection-matched EUV illumination/imaging fields and pupils with the capability to perform RTD in both imaging modes of the sensor (e.g., scanning and frame), allowing emulation of APMI conditions and capturing metrics such as pupil imaging that require frame mode imaging. In embodiments, the measurements according to the present disclosure may be executed within inspection at frequencies determined by the system drift time scales.

In embodiments, a diagnostic scheme according to the present disclosure allows for periodic polling of the critical system metrics with the same field and pupil characteristics as the inspection, requires APMI level image quality on the RTD targets, provides the ability to swiftly move the system FOV between APMI and RTD using the same stage used for APMI, allows RTD polling with different architectures for low operational polling cadence sufficient to monitor slow drifts or high operational polling cadence with maximum measurement polling that can be as large as the number of swaths in inspection or at, for example, the beginning and end of each swath. In a first configuration of the RTD targets, the APMI EUV may be paused to navigate along a path (e.g., non-linear) to reach the RTD targets (e.g., miniaturized RTD targets implemented as EUV calibration chips that support step access from any swath location). In a second configuration of the RTD targets, the APMI may be paused while continuously moving along a linear imaging path to reach the RTD targets (e.g., miniaturized RTD targets implemented as elongated EUV reticle bars having a length substantially corresponding to a length of the reticle of the EUV lithography mask to allow RTD access by contiguous swath access at the beginning and/or end of each swath).

In embodiments, the diagnostic targets according to the present disclosure may be EUV reticle-based diagnostic targets fabricated to provide known and optimal imaging contrast and reflectivity at EUV wavelength (e.g., EUV RTD targets having an EUV stack). In embodiments, using a pre-engineered EUV reticle for RTD obviates the need for a customer-supplied EUV reticle and further allows system specific target pattern designs independent of the ever-changing patterns on customer-supplied EUV reticles. In embodiments, the RTD targets may be compact and have a small footprint (e.g., miniaturized), and may be positioned proximally/adjacent/contiguous to the EUV lithography mask(s) to be inspected (e.g., accessible within the available finite stroke range of the APMI stage in all degrees of freedom) to minimize disruption to the inspection process. In embodiments, the RTD targets may be pre-engineered with known EUV performance including, but not limited to, EUV pupil (EUV-P), EUV focus (EUV-F), and EUV wavefront error (EUV-WFE). In embodiments, the RTD targets may be a repository of system relevant EUV patterns (e.g., multilayer, absorber, black border, blazed black border, etc.). In embodiments, the concept of diagnostic targets for RTD may extend to non-EUV based inspection systems including, but not limited to, optical and electron-based inspection systems.

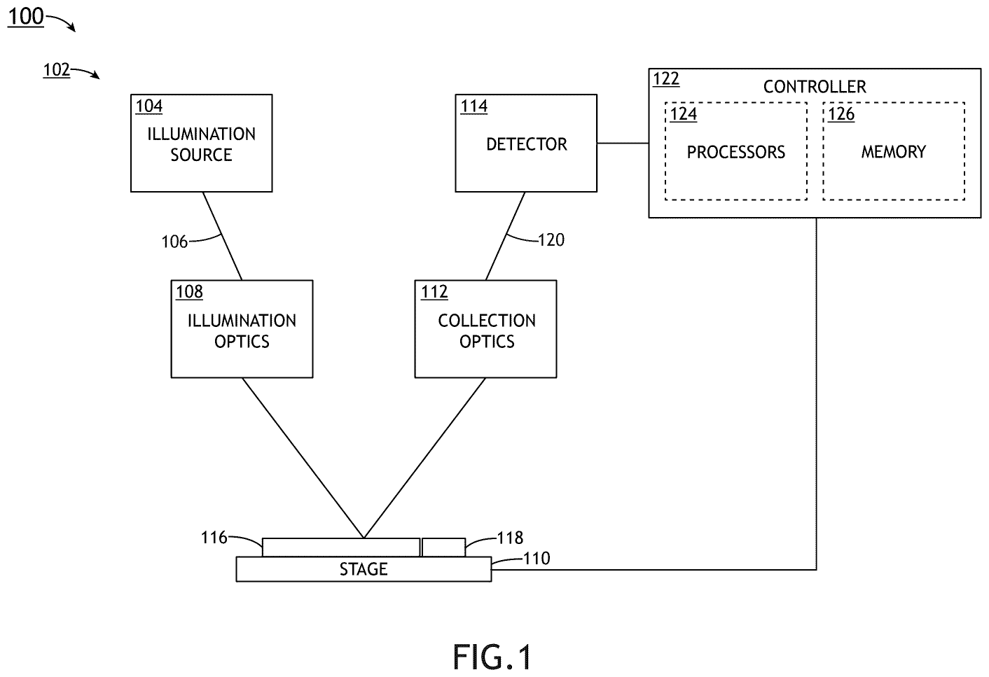

FIG. 1 schematically illustrates a lithography mask inspection system 100, in accordance with one or more embodiments of the present disclosure. In embodiments, the inspection system 100 includes a reticle inspection sub-system 102 including an illumination source 104 configured to generate a beam of illumination 106. The beam of illumination 106 may be optical and include one or more selected wavelengths of light including, but not limited to, ultraviolet (UV), deep ultraviolet (DUV), vacuum ultraviolet (VUV) radiation, extreme ultraviolet (EUV), etc. In a particular conceived example, the inspection system 100 is an actinic patterned mask inspection (APMI) system and the illumination source 104 is an EUV light source configured to generate a beam of EUV illumination (e.g., 13.5 nm). In embodiments, the inspection system 100 may be an electron beam (e-beam) inspection system in which case the illumination is electron beam.

The illumination source 104 may be any type of illumination source, e.g., optical or electron-based, known in the art suitable for generating a beam of illumination 106. In embodiments, the illumination source 104 includes a broadband plasma (BBP) illumination source that encompasses the emission in actinic wavelength or a narrow band plasma source that selectively emits at EUV such as from a synchrotron. In embodiments, the illumination source 104 may include one or more lasers capable of emitting radiation at one or more selected wavelengths. In embodiments, the illumination source 104 includes an electron beam source such as an electron gun.

In embodiments, the reticle inspection sub-system 102 includes a first set of optical elements including illumination optics 108 configured to direct the beam of illumination from the illumination source 104 to a stage 110, and a second set of optics 112 (e.g., collection optics) configured to magnify and image the illuminated substrate or one or more diagnostic target discussed in detail below. The reticle inspection sub-system 102 further includes a detector 114 configured to detect the magnified image of the illumination FOV on the substrate. In use, the optical elements are operable for at least one of directing, focusing, and shaping the beam of illumination 106. For example, the optical elements may include one or more lenses or mirrors, one or more focusing elements, etc. In embodiments, the optical elements may include any combination of reflective, transmissive, or absorbing optical elements known in the art suitable for directing and/or focusing the beam of illumination 106.

In embodiments, the stage 110 is encompassed by the field of view of the reticle inspection sub-system 102 and defines a first portion for positioning a substrate 116 (e.g., lithography mask) to be inspected and a second portion for positioning one or more diagnostic targets 118 (e.g., reticle-based diagnostic targets) as discussed in detail below. In embodiments, the stage 110 may be configured to secure in place the substrate 116 and the one or more diagnostic targets 118. The stage 110 may include any device suitable for positioning and/or scanning the substrate 116 and the one or more diagnostic targets 118 within the inspection system 100. For example, the stage 110 may include any combination of linear translation stages, rotational stages, tip/tilt stages, or the like. In alternative embodiments, the stage 110 may be fixed and the reticle inspection sub-system 102 or elements thereof may be movable relative to the stage 110, or each of the stage 110 and the reticle inspection sub-system 102 or elements thereof may be movable.

In embodiments, the detector 114 is configured to capture light/electrons emanating from the substrate 116 and the one or more diagnostic targets 118 through a collection pathway 120. The collection pathway 120 includes the second set of optics 112 (e.g., collection optics) configured to collect radiation directed from the substrate 116 and the one or more diagnostic targets 118. The second set of optics 112 may include any combination of reflective, transmissive, and absorbing optical elements known in the art suitable for directing and/or focusing the collected light. The detector 114 may include any type of detector known in the art suitable for measuring collected illumination, such as EUV light or electron beams. For example, the detector 114 may include, but is not limited to, a CCD detector, a TDI detector, a photomultiplier tube (PMT), an avalanche photodiode (APD), an electron detector, etc.

In embodiments, the inspection system 100 includes a controller 122, which may be part of the reticle-inspection sub-system 102. In embodiments, the controller 122 includes one or more processors 124 configured to execute program instructions maintained in a memory 126. In this regard, the one or more processors 124 of controller 122 may execute any of the various process steps described throughout the present disclosure. In embodiments, the controller 122 includes hardware and software elements. The controller 122 may be communicatively coupled with any component of the inspection system 100 or any additional components outside of the inspection system 100. In embodiments, the controller 122 may be configured to receive data from a component such as, but not limited to, the detector 114. For example, the controller 122 may receive any combination of raw data, processed data (e.g., inspection results), and/or partially processed data. In another embodiment, the controller 122 may perform processing steps based on the received data. For example, the controller 122 as it pertains to the lithography mask 116 may perform defect inspection steps including defect identification, classification, and sorting, and as it pertains to the one or more reticle-based diagnostic targets may measure critical imaging metrics used during inspection, for instance EUV imaging metrics including, but not limited to, EUV-P, EUV-F, and EUV-WFE. In embodiments, the controller 122 may be configured to inspect, pause inspection, move the field of view (e.g., stage translation), measure, determine, calibrate, restart inspection, etc.

In embodiments, the controller 122 may control and/or direct (e.g., via control signals) any component of the inspection system 100. For example, any combination of elements associated with the illumination pathway and/or the collection pathway may be adjustable. In this regard, the controller 122 may modify any combination of illumination conditions or imaging conditions such as, but not limited to, the illumination or imaging pupil distributions.

The inspection system 100 may be configured as any type of inspection known in the art. Further, the inspection system 100 may be, but is not required to be, an EUV inspection system 100 suitable for interrogating a substrate 116 (e.g., lithography mask) and the one or more diagnostic targets 118 with EUV light. EUV-based mask blank inspection is described generally in U.S. Pat. No. 8,711,346 to Stokowski, issued on Apr. 29, 2014, and U.S. Pat. No. 8,785,082 to Xiong et al., issued on Jul. 22, 2014, both of which are incorporated herein by reference in the entirety. In another embodiment, the inspection system 100 may be configured as a wafer inspection system or a reticle inspection system. EUV imaging is described generally in U.S. Pat. No. 8,842,272 to Wack, issued on Sep. 23, 2014, which is incorporated herein by reference in the entirety.

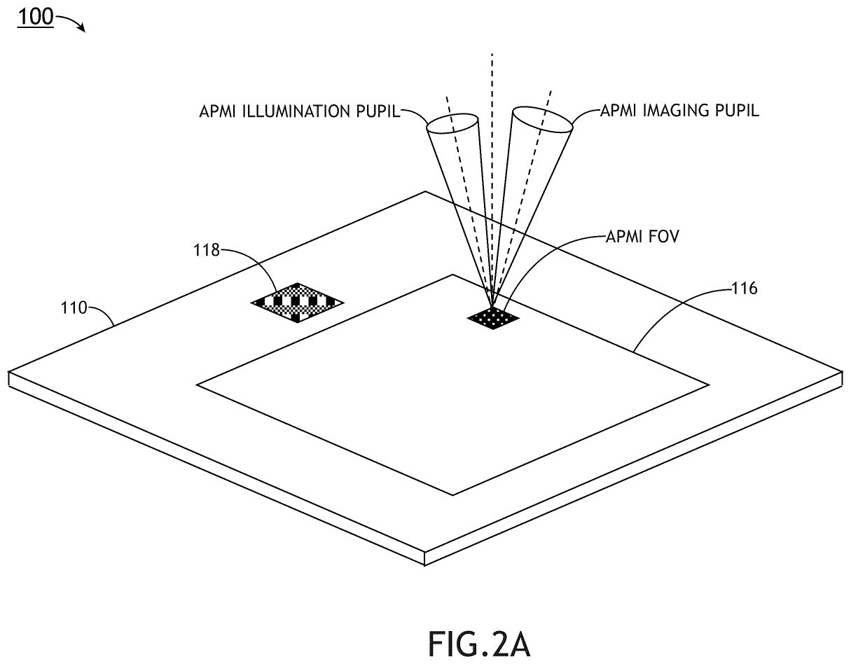

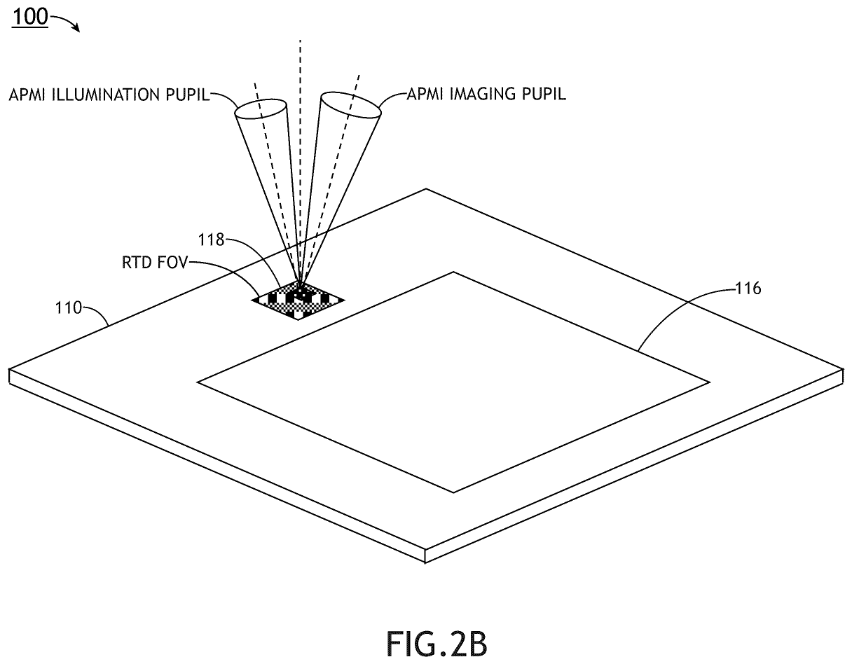

FIGS. 2A and 2B illustrate schematically the inspection system 100, and specifically the system field of view (FOV) and pupil shared and moved between substrate inspection (e.g., mask inspection) and RTD. Referring to FIG. 2A, for mask inspection such as APMI mask inspection, the system FOV and pupil are focused on the EUV reticle 200 associated with the substrate/lithography mask to be inspected. Referring to FIG. 2B, for RTD and system health check in an EUV-based system, the same FOV and pupil are moved to focus on the one or more EUV reticle-based diagnostic targets 118. In embodiments, the lithography mask and the one or more EUV reticle-based diagnostic targets 118 are positioned on the stage 110 and in close proximity such that the same FOV and pupil can be moved between the two targets to switch between APMI and RTD. In embodiments, the one or more EUV reticle-based diagnostic targets 118 preferably have a comparatively small footprint in order to share the stage and be encompassed with the system FOV.

In embodiments, the diagnostic targets 118 may be a repository of all system relevant patterns. In the case of EUV reticle-based diagnostic targets 118, the targets preferably support high contrast and high EUV photon rate and hence can be used for accurate measurements of all EUV system metrics. Non EUV-based diagnostic targets may also be utilized for non-EUV based inspection systems (e.g., optical and electron based) including, but not limited to, chrome on glass.

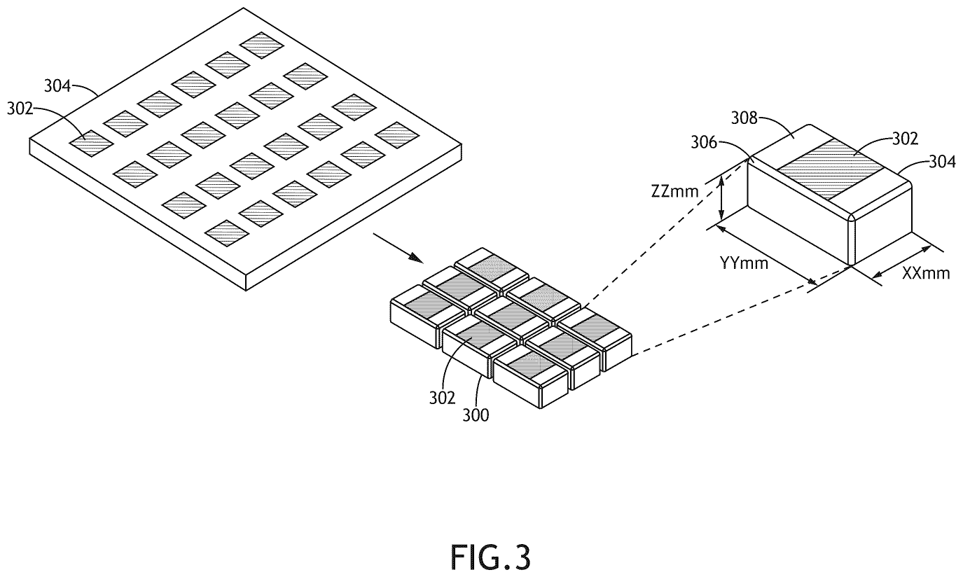

FIG. 3 illustrates EUV reticle-based diagnostic targets 118 implemented as EUV calibration chips 300 configured to support step access (e.g., x and y axis navigation) from any swath location. In embodiments, the calibration chips 300 are based on the concept of an EUV stack or derived from an industry standard EUV reticle for measuring the critical EUV imaging metrics used during inspection (e.g., EUV-P, EUV-F, EUV-WFE, etc.) and subject to drift. In embodiments, the EUV calibration chips 300 may be fabricated in mass from a patterned parent reticle 302 positioned in repeat on a substrate layer 304 which is then diced to produce a plurality of individual calibration chips 300. In embodiments, the reticle patterning 302 may be matched to the reticle patterning of the EUV substrate (e.g., lithography mask) to be inspected. Various reticle patterning can be created by combining patterning tones including, but not limited to, absorber, multilayer, black border, blazed black border, etc.

In embodiments, each calibration chip 300 may be dimensioned to position the patterned reticle 302 of the calibration chip 300 in the reticle plane of the substrate reticle and permit close spacing to the reticle substrate (e.g., lithography mask 116). For example, as it pertains to stage positioning, each calibration chip 300 may have a z axis dimension between about 6.25 mm and about 6.45 mm, and more preferably between about 6.30 mm and about 6.40 mm, may have a y axis dimension no more than about 50.0 mm, and preferably no more than about 20.0 mm, and may have an x axis dimension no more than about 50.0 mm, and preferably no more than about 20.0 mm. In embodiments, each calibration chip 300 may have chamfered edges 306 formed at the intersection of the adjacent faces and black bordering 308 positioned adjacent the reticle patterning 302 for chip clamping to the stage 110.

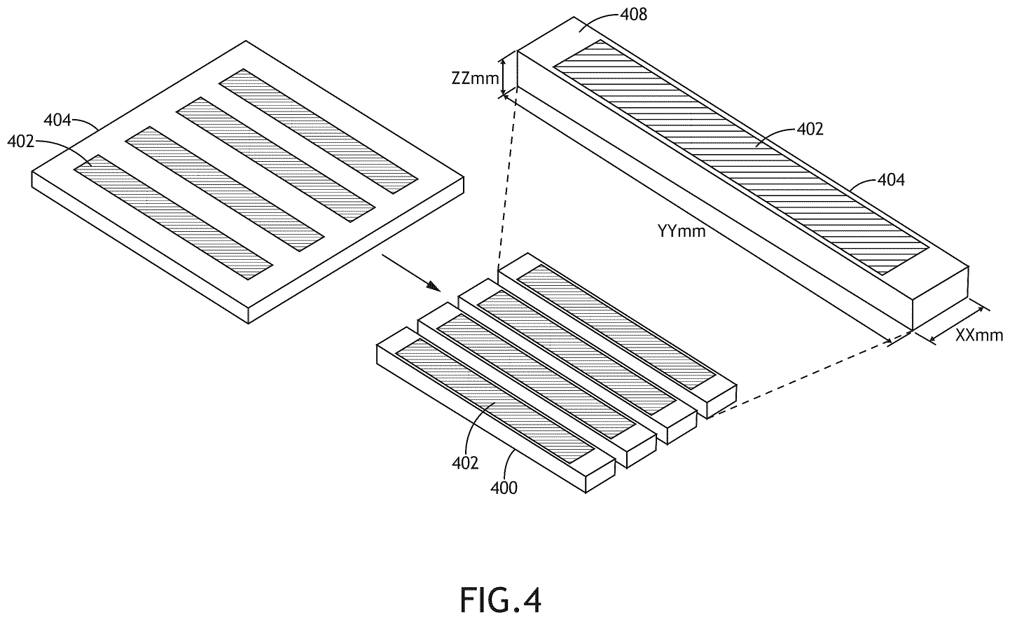

FIG. 4 illustrates EUV reticle-based diagnostic targets 118 implemented as EUV calibration bars 400 configured to support contiguous swath access. In embodiments, the calibration bars 400 are also based on the concept of an EUV stack or derived from an industry standard EUV reticle for measuring the critical EUV imaging metrics used during inspection (e.g., EUV-P, EUV-F, EUV-WFE, etc.) and subject to drift. In embodiments, the EUV calibration bars 400 may be fabricated in mass from a patterned parent reticle 402 positioned in repeat on a substrate layer 404 which is then diced to produce a plurality of individual elongated calibration bars 400. In embodiments, the reticle patterning 402 may be matched to the reticle patterning of the EUV substrate (e.g., lithography mask) to be inspected. Various reticle patterning can be created by combining patterning tones including, but not limited to, absorber, multilayer, black border, blazed black border, etc.

In embodiments, each calibration bar 400 may be dimensioned to position the patterned reticle 402 of the calibration bar 400 in the reticle plane of the substrate reticle and permit close spacing to the reticle substrate (e.g., lithography mask 116). For example, as it pertains to stage positioning, each calibration bar 400 may have a z axis dimension between about 6.25 mm and about 6.45 mm, and more preferably between about 6.30 mm and about 6.40 mm, may have a y axis dimension no more than about 150.0 mm, and preferably no more than about 130.0 mm, and may have an x axis dimension no more than about 50.0 mm, and preferably no more than about 20.0 mm (with the x axis of the stage corresponding to the swathing direction for inspection). In embodiments, each calibration bar 400 may or may not have chamfered edges formed at the intersection of the adjacent faces. In embodiments, each calibration bar 400 has black bordering 408 positioned adjacent the reticle patterning 402 for chip clamping to the stage 110.

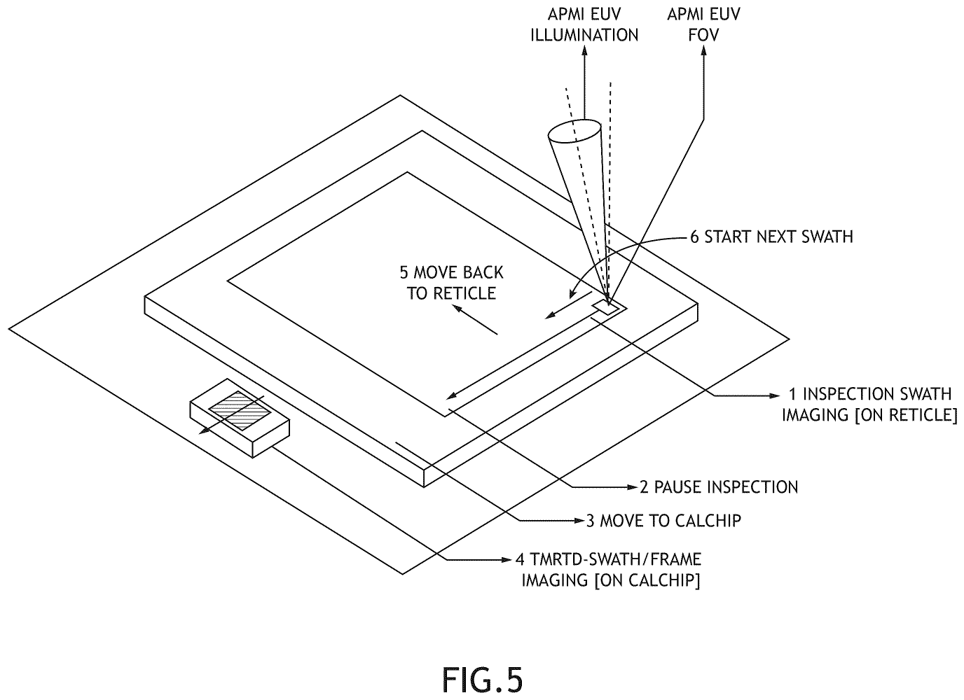

FIG. 5 illustrates schematically the use of an RTD diagnostic target implemented as a calibration chip 300 used to perform RTD in an inspection system 100, for instance an APMI system for substrate (e.g., mask) inspection. In embodiments, the substrate 500 (e.g., mask, reticle, etc.) having a surface to be inspected is secured on the stage 110 proximal to a calibration chip 300 having the predefined patterned reticle 302 of known EUV performance, and also secured on the stage 110. In embodiments, the surface to be inspected and the patterned reticle 302 of the calibration chip 300 are positioned coplanar.

During inspection, for instance during APMI inspection, swath images of a patterned zone of the substrate are taken to collect data to check for defects in the substrate. In embodiments, each image scan may correspond to a swath across the surface to be inspected, for instance along the x axis of the stage 110. Multiple swaths are typically required to image the substrate considering the comparatively small FOV of the EUV illumination. At any time during inspection, for instance between swaths or between a predefined number of swaths, the inspection may be paused to navigate the FOV to the calibration chip 300 to perform the RTD to determine the performance of the system, and particularly the measurement metrics as described above which are prone to drift over time. Depending on the disposition of the calibration chip 300 to the last swath taken, movement of the FOV to the calibration chip 300 may require stepping the x and y directions to the calibration chip 300 and then imaging the RTD target in swath in x/frame mode.

Considering the patterned reticle 302 has a known EUV performance, the collected data can be used to recalibrate the system as necessary to ensure correct/optimal performance. Once system performance has been confirmed and/or recalibrated, the FOV is returned to the patterned zone 502 for continued inspection (e.g., start the next swath). The polling frequency at which the inspection is paused and the system checked for image quality performance may correspond to the drift rates of the critical system parameters that have a direct impact on the actinic image quality (e.g., EUV-P, EUV-F, and EUV-WFE). For example, low operational polling cadence may be sufficient to monitor slow drifts whereas high operational polling cadence may be required at the beginning and/or end of each swath for maximum measurement polling.

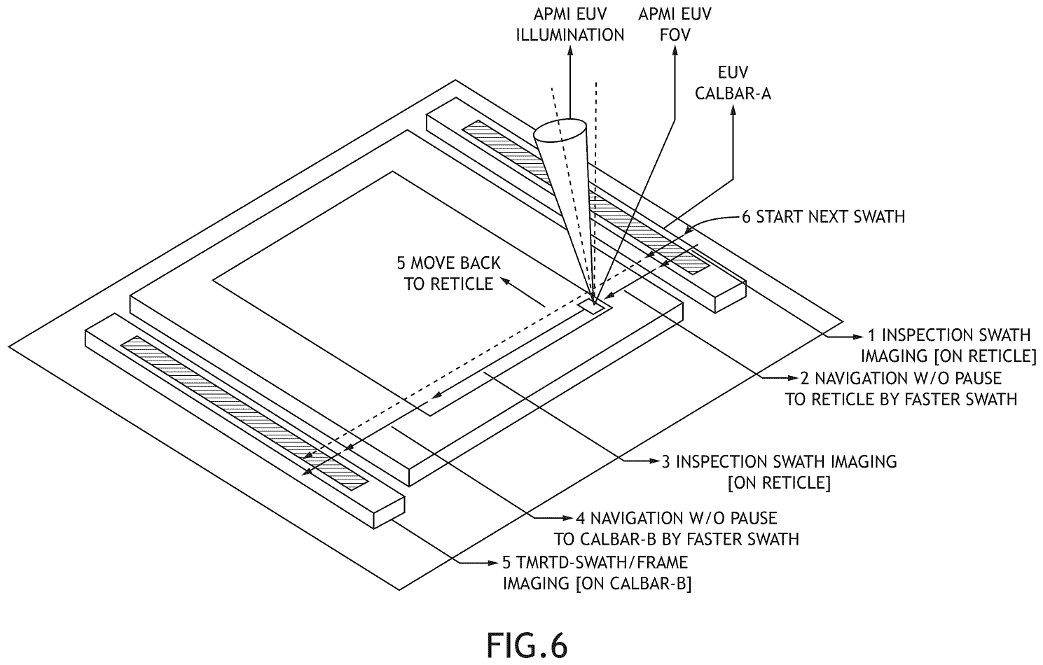

FIG. 6 illustrates schematically the use of one or more RTD targets implemented as calibration bars 400 used to perform RTD in an inspection system 100, for instance an APMI system for substrate (e.g., mask) inspection. In embodiments, the substrate 500 (e.g., mask, reticle, etc.) to be inspected is secured on the stage 110 proximal to one or more calibration bars 400, for example two calibration bars 400 positioned along opposing sides of the substrate 500 to be swath imaged along the x axis. Each calibration bar 400 has a predefined patterned reticle 402 of known EUV performance and is secured on the stage 110. In embodiments, the surface to be inspected and the patterned reticles 402 of the calibration bars 400 are positioned coplanar.

During inspection, for instance during APMI inspection, swath images of a patterned zone 502 of the substrate are taken to collect data to check for defects in the substrate. In embodiments, each image scan may correspond to a swath across the surface to be inspected, for instance along the x axis of the stage 110. Multiple swaths are typically required to image the substrate considering the comparatively small FOV of the EUV illumination. Considering the corresponding ‘lengths’ of the patterned reticle 402 and the patterned zone 502 of the substrate, contiguous swaths (e.g., along the x axis) can include surface inspection and RTD measurements. For example, for each swath, APMI can be paused while continuously moving the FOV in the along the x axis to reach the calibration bar 400 to image the patterns by swathing on the calibration bar 402 to determine system performance, and particularly the measurement metrics of the system as described above which are prone to drift over time. In the case of two calibration bars 400 positioned on opposing sides of the substrate 500, calibration swaths can be performed at the beginning and/or end of each swath in case of the need for high operational polling cadence.

Regardless of which type of RTD target is utilized, both RTD target types positioned on the same stage as the substrate 500 and in close proximity (e.g., adjacent) thereto provide the ability to swiftly move the system FOV between APMI and RTD to measure the critical system metrics (e.g., EUV system metrics) during inspection. Thus, the RTD targets perform as stand-alone miniaturized reticles and pattern repositories for system health checks, enabling RTD with the highest image contrast and reflectivity and with variable polling architectures.

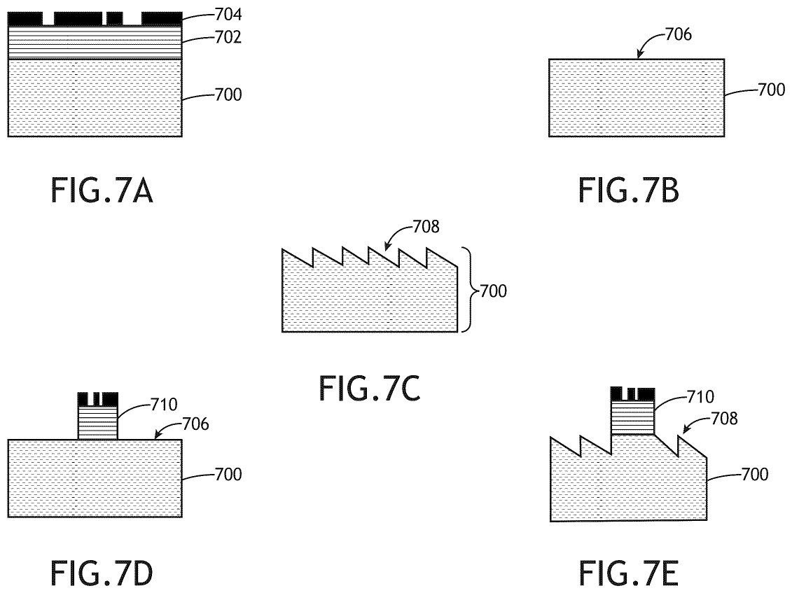

FIGS. 7A-7E illustrates various patterning (e.g., EUV patterning) for the RTD targets according to the present disclosure. In embodiments, the RTD targets may include standard and novel EUV patterns including one or more of absorber, multilayer, black border, and blazed black border patterning. FIG. 7A illustrates a standard EUV pattern including a substrate layer 700, a multilayer stack 702 disposed on the substrate layer 700, and an absorber layer 704 disposed on the multilayer stack 702. In embodiments, the multilayer stack 702 may include several alternating layers of reflective material. In embodiments, the absorber layer 704 may be configured to absorb incident illumination and/or reflective illumination. In embodiments, portions of the absorber layer 704 and/or multilayer stack 702 may be etched to form a predefined pattern.

FIG. 7B illustrates black bordering 706 for forming dark zones for EUV light that are substantially attenuated relative to patterned areas, such as the patterned areas forming selective reflection or emission of incident illumination by the multilayer stack 702 and/or absorber layer 704. Traditionally, dark zones may include areas of the substrate layer 700 that do not include a multilayer stack 702 or an absorber layer 704. Traditional black borders that rely on non-structured glass substrate for reducing intrinsic reflectivity are referred to as normal black borders (NBB), whereas black borders that rely on textured areas for reducing reflection are referred to as hybrid black borders (HBB). FIG. 7C illustrates a black border produced by gratings 708 referred to as deep black borders (DBB). In embodiments, the gratings 708 may be composed of substrate material (e.g., from the substrate layer 700) or may be formed from other material that has been applied to the surface of the substrate layer 700.

FIG. 7D illustrates an EUV patterned island 710 disposed on an NBB 706. In embodiments, the RTD targets may include a singular EUV patterned island 710 or multiple EUV patterned islands 710 positioned in spaced apart relation. In embodiments, each EUV patterned island 710 may include a multilayer stack 702 and an etched absorber layer 704. FIG. 7E illustrates an EUV patterned island 710 disposed on an NBB plateau surrounded by DBBs 708. Other configurations of RTD target patterning is envisioned. In embodiments, the EUV layers and pattern combinations may emulate the APMI EUV targe reticle.

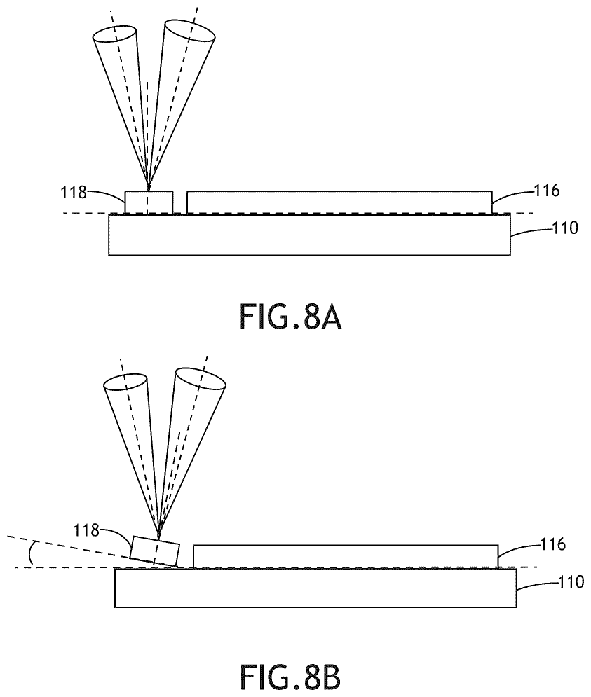

FIGS. 8A and 8B illustrate orientations of the RTD targets 118 relative to the reticle plane of the inspection system. FIG. 8A illustrates a first orientation in which the RTD target 118 (e.g., calibration chip 300 or calibration bar 400) is oriented level with the stage 110 and surface of the substrate 500 to be inspected. In embodiments, level orientation may require serial or sequential through focus measurements of the RTD target 118. FIG. 8B illustrates a second orientation in which the RTD target 118 (e.g., calibration chip 300 or calibration bar 400) is tilted relative to the stage 110 and the surface of the substrate 500 to be inspected. In embodiments, a tilted orientation may facilitate through focus capture in one continuous swath to speed throughout. In embodiments, the tilt angle may range between about 1.0 mrad and about 5.0 mrad, more preferably between about 1.0 mrad and about 3.0 mrad, and even more preferably between about 1.0 mrad and about 2.0 mrad. In some embodiments, the tilt angle is 2.0 mrad.

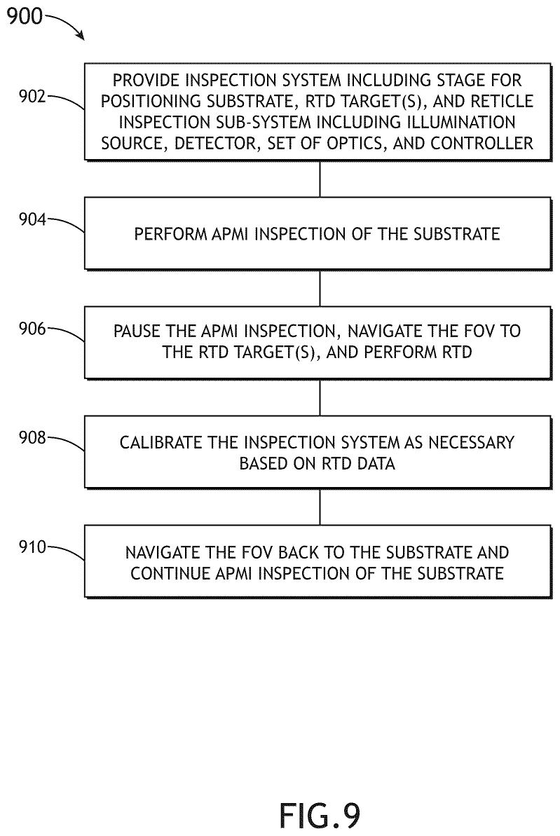

FIG. 9 illustrates a process flow diagram depicting a method 900 for performing APMI and RTD within the same inspection tool. In step 902, the method includes providing an inspection system including a stage configured to position a substrate (e.g., EUV lithography mask) to be inspected, one or more diagnostic targets positioned on the stage, and a reticle inspection sub-system having a field of view encompassing the stage, the reticle inspection sub-system including an illumination source, optical elements, a detector, and a controller. In step 904, the method includes performing APMI inspection of the substrate using the inspection tool. In step 906, the method includes pausing the APMI inspection, navigating the FOV to the one or more reticle-based diagnostic targets, and performing RTD. In step 908, the method includes calibrating the system as necessary based on data collected from the RTD. In step 910, the method includes navigating the FOV back to the substrate and continuing the APMI inspection of the substrate. In embodiments, the steps repeat as necessary to ensure system health.

In embodiments, the one or more processors 124 of the controller 122 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 124 may include any device configured to execute algorithms and/or instructions (e.g., program instructions stored in memory). In embodiments, the one or more processors 124 may be embodied as a desktop computer, mainframe computer system, workstation, image computer, parallel processor, networked computer, or any other computer system configured to execute a program configured to operate or operate in conjunction with the inspection system, as described throughout the present disclosure.

The memory 126 may include any storage medium known in the art suitable for storing program instructions executable by the associated one or more processors 124. For example, the memory 126 may include a non-transitory memory medium. By way of another example, the memory 126 may include, but is not limited to, a read-only memory (ROM), a random-access memory (RAM), a magnetic or optical memory device (e.g., disk), a magnetic tape, a solid-state drive and the like. It is further noted that memory 126 may be housed in a common controller housing with the one or more processors 124. In embodiments, the memory 126 may be located remotely with respect to the physical location of the one or more processors 124 and the controller 122. For instance, the one or more processors 124 of the controller 122 may access a remote memory (e.g., server), accessible through a network (e.g., internet, intranet and the like).

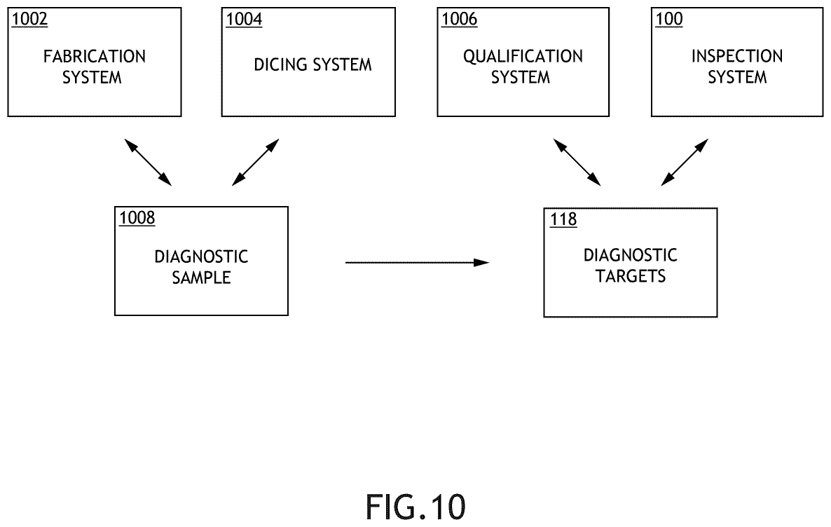

Referring now to FIGS. 10-15B, the fabrication of one or more diagnostic targets 118 is described in greater detail, in accordance with one or more embodiments of the present disclosure.

The fabrication of high-quality diagnostic targets 118 presents unique challenges in maintaining the precision and reliability required for accurate system diagnostics. In some aspects, conventional approaches to manufacturing diagnostic targets may suffer from inconsistent quality, limited scalability, and inadequate performance characteristics that can compromise the effectiveness of runtime diagnostics. The diagnostic targets 118 may require stringent specifications for dimensional accuracy, surface quality, pattern fidelity, and material properties to ensure reliable measurement of critical system parameters such as EUV-P, EUV-F, and EUV-WFE. In some cases, variations in target quality can lead to measurement uncertainties that may propagate through the diagnostic process, potentially resulting in incorrect system calibrations or missed drift detection.

Embodiments of the present disclosure are directed to systems and methods for fabricating one or more diagnostic targets 118 by dicing a diagnostic sample fabricating using a high-yield fabrication process and dicing the diagnostic sample into the diagnostic targets. This high-yield process may be the same type of process used to fabricate runtime samples that are configured for use in process tools such as inspection tools, metrology tools, or lithography tools. For example, in the case of EUV-based systems as described with respect to FIGS. 1-9, the diagnostic sample may be fabricated using the same EUV reticle manufacturing processes employed for production EUV masks, including multilayer deposition, absorber patterning, and quality control procedures. This approach may leverage established manufacturing infrastructure and proven process capabilities to ensure consistent quality and performance of the resulting diagnostic targets 118.

The use of a high-yield fabrication process for creating diagnostic targets 118 may provide several advantages over conventional manufacturing approaches. In some aspects, the process may utilize industry-standard equipment, materials, and procedures that have been optimized for high throughput and consistent quality. The diagnostic sample may be patterned with multiple diagnostic target designs in a single fabrication run, allowing for efficient production of numerous targets with uniform characteristics. In embodiments, the diagnostic sample may then be diced into individual diagnostic targets 118, such as calibration chips 300 or calibration bars 400, each maintaining the high-quality characteristics imparted by the fabrication process. This manufacturing approach may enable the production of diagnostic targets 118 with known and predictable performance characteristics, facilitating accurate and reliable diagnostics (e.g., runtime diagnostics).

The systems and methods disclosed herein may be adapted for generating diagnostic targets 118 for any type of process tool including, but not limited to, an inspection tool (e.g., an EUV or DUV inspection tool), a metrology tool, or a lithography tool.

In embodiments, the fabrication approach may be applied to create diagnostic targets for optical inspection tools operating at different wavelengths. For example, deep ultraviolet (DUV) or visible light systems may utilize diagnostic targets where the diagnostic sample is fabricated using chrome-on-glass or other optical mask technologies. For example, metrology tools may employ diagnostic targets 118 with specialized patterns designed to measure critical dimensions, overlay accuracy, or film thickness, with the diagnostic sample fabricated using processes similar to those employed for production wafers or test structures. For example, lithography tools may utilize diagnostic targets 118 fabricated with resolution test patterns, focus monitoring structures, or dose sensitivity patterns, where the diagnostic sample may be created using the same photoresist processing and substrate preparation techniques used for production photomasks.

The versatility of this manufacturing approach may extend to electron beam inspection systems, where diagnostic targets 118 may be fabricated with conductive patterns or charging control structures using semiconductor fabrication processes. In embodiments, X-ray inspection systems may benefit from diagnostic targets 118 created with high-contrast materials and absorption patterns fabricated using processes similar to those used for X-ray masks or filters. The scalability of the dicing approach may allow for the production of diagnostic targets 118 tailored to specific tool requirements, such as varying target sizes for different field-of-view configurations or specialized pattern geometries for particular measurement algorithms. This unified manufacturing strategy may provide consistent quality control and traceability across different process tool types while leveraging established fabrication infrastructure and expertise.

In some embodiments, protective measures may be implemented during the dicing and cleaning processes to maintain the integrity of the diagnostic patterns. Resists developed and used by the semiconductor industry that are compatible with EUV masks may be applied to protect patterns against particles and chemical contaminants during dicing and cleaning operations. These industry-standard resists may provide a temporary protective barrier over sensitive patterned areas, preventing damage from cutting debris, cleaning chemicals, or airborne contaminants that could compromise pattern fidelity. Additionally, specialized tapes developed and used by the semiconductor industry that are compatible with EUV masks may be employed to provide mechanical protection during handling and processing operations. In some cases, both protective resists and protective tapes may be used simultaneously to provide comprehensive protection, with the resist protecting against chemical exposure and fine particles while the tape provides mechanical shielding and handling protection.

To facilitate the integration of the resulting diagnostic targets 118 with existing inspection infrastructure, specialized adaptors may be developed to enable loading of calibration chips 300 into existing mask inspection tools. These adaptors may accommodate the smaller dimensions of the diagnostic targets 118 compared to standard EUV masks while maintaining proper mechanical registration and optical alignment within the inspection system. The adaptors may be designed to interface with existing stage mechanisms and clamping systems, allowing the diagnostic targets 118 to be positioned accurately within the inspection field of view without requiring modifications to the primary inspection tool hardware. This approach may enable the use of established inspection and qualification equipment for evaluating the diagnostic targets 118, providing consistent measurement capabilities and leveraging existing calibration procedures.

In some embodiments, the manufacturing process may be configured to establish high yield production verified through comprehensive EUV/DUV chip inspection protocols. In some embodiments, the high yield may be achieved by optimizing the dicing parameters, protective measures, and handling procedures to minimize defects and maintain pattern integrity across the entire production run. The yield verification may involve systematic inspection of representative samples from each production batch using EUV or DUV inspection systems to assess dimensional accuracy, pattern fidelity, and surface quality. In some cases, the inspection protocols may include automated defect detection algorithms that can identify and classify various types of manufacturing defects, enabling continuous process improvement and yield optimization. The high yield manufacturing approach may ensure that a substantial percentage of the diced diagnostic targets 118 meet the stringent quality requirements for process tool calibration applications.

In some embodiments, the cleanliness requirements for individual diagnostic targets 118 may be established and verified through particle detection systems capable of identifying contaminants as small as 30 nm in diameter. In some embodiments, the cleanliness verification may be performed using EUV or DUV inspection tools equipped with high-resolution particle detection capabilities that can scan the entire surface of each diagnostic target. The inspection process may differentiate between different regions of the diagnostic targets, applying more stringent cleanliness standards to the patterned areas while allowing for relaxed requirements on non-critical surfaces such as sidewalls 1502 or mounting areas. In some cases, the particle inspection may be integrated with pattern damage assessment to provide comprehensive quality evaluation in a single inspection pass. The process may also incorporate damage-free verification protocols that confirm the integrity of EUV patterns and multilayer stack 702 structures following the application and removal of protective resists or tapes, ensuring that the shielding procedures do not compromise the optical performance of the diagnostic targets 118.

In some embodiments, to enhance manufacturing throughput and efficiency, multi-chip adaptors may be developed to enable simultaneous inspection of several diagnostic targets 118 in each inspection session. In some embodiments, these adaptors may be configured to accommodate different sizes and shapes of diagnostic targets, providing flexibility for custom applications while maintaining inspection accuracy and repeatability. The multi-chip inspection capability may significantly reduce the time required for quality verification, enabling higher production volumes and faster turnaround times for diagnostic target manufacturing. In some cases, the manufacturing process may be adapted to create diagnostic targets 118 with custom dimensions and geometries tailored to specific process tool requirements, such as specialized calibration chips 300 for particular measurement algorithms or calibration bars 400 with non-standard aspect ratios for unique inspection configurations. This customization capability may allow the manufacturing process to address diverse application needs while maintaining the same high-quality fabrication standards and verification procedures.

FIG. 10 illustrates a block diagram of a system for manufacturing diagnostic targets, in accordance with one or more embodiments of the present disclosure. The system includes a fabrication system 1002 configured to fabricate patterns on a diagnostic sample 1008 using established fabrication processes. In some cases, the fabrication system 1002 may utilize the same fabrication processes employed for manufacturing runtime samples that are configured for use in process tools such as, but not limited to, the inspection system 100. The fabrication system 1002 may be configured to create patterns on the diagnostic sample 1008 that are designed to provide diagnostics of process tools, enabling accurate measurement of system parameters and performance characteristics.

The fabrication system 1002 may include any type of process tools such as, but not limited to, a lithography tool for pattern transfer (e.g., an EUV lithography system operating at 13.5 nm wavelength, or any other suitable wavelength), an etching tool for selective material removal (e.g., a reactive ion etching system for multilayer patterning), or a polishing tool for surface preparation and finishing (e.g., a chemical mechanical polishing system for achieving precise thickness control and surface flatness required for high-quality diagnostic targets).

The system further includes a dicing system 1004 that may be configured to dice the diagnostic sample 1008 into a plurality of the one or more diagnostic targets 118 after pattern fabrication. In some cases, the dicing system 1004 may include a blade dicing tool that utilizes precision cutting mechanisms to separate individual diagnostic targets from the diagnostic sample 1008. In other cases, the dicing system 1004 may include a laser dicing tool that employs focused laser energy to cut through the diagnostic sample 1008 material. The dicing system 1004 may be configured to maintain dimensional accuracy and minimize damage to the patterned areas during the cutting process, ensuring that each of the one or more diagnostic targets 118 retains the pattern fidelity established during fabrication.

A qualification system 1006 may be connected to the dicing system 1004 and configured to generate one or more quality metrics for the plurality of the one or more diagnostic targets 118 produced by the dicing process. The qualification system 1006 may include various measurement and inspection tools configured to evaluate dimensional tolerances, particle contamination limits, pattern fidelity requirements, and molecular cleanliness requirements of the diced diagnostic targets. In some cases, the qualification system 1006 may employ scanning electron microscopy tools for pattern fidelity assessment, particle detection systems for contamination analysis, gas chromatography-mass spectrometry (GC-MS) for molecular contamination analysis, and dimensional measurement equipment for verifying target specifications. The qualification system 1006 may be configured to filter out any of the plurality of the one or more diagnostic targets 118 that do not meet selected quality standards, ensuring that only qualified targets proceed to final packaging and deployment.

The system may further include a controller that contains one or more processors configured to execute program instructions for coordinating the operation of the fabrication system 1002, dicing system 1004, and qualification system 1006. The controller may be configured to manage the flow of the diagnostic sample 1008 through the manufacturing process, monitor quality metrics generated by the qualification system 1006, and implement quality control decisions based on predetermined standards. In some cases, the controller may automatically direct qualified diagnostic targets to packaging operations while routing non-conforming targets for rework or disposal.

The controller described above may incorporate the same features and capabilities as the controller 122 described with respect to the inspection system 100, including one or more processors 124 and memory 126 configured to execute program instructions for system operation and control. In embodiments, this manufacturing system controller may utilize similar hardware and software architectures, memory configurations, and processing capabilities as described for the inspection system controller 122, enabling coordinated operation across both manufacturing and inspection operations. The controller may be configured to interface with remote systems, access networked resources, and implement the same types of control algorithms and decision-making processes described throughout the present disclosure for inspection system operations.

The system architecture may also incorporate one or more post-dicing processing tools configured to perform additional processing of the one or more diagnostic targets 118 after dicing operations. These post-dicing processing tools may be configured to perform polishing of diced surfaces to achieve specified surface roughness requirements, chamfering of edges to prevent damage during handling and installation, or cleaning operations to remove particles and contaminants introduced during the dicing process. In some cases, the post-dicing processing tools may include chemical cleaning systems, mechanical polishing equipment, and edge finishing tools that work in coordination to prepare the diagnostic targets for qualification testing.

The manufactured one or more diagnostic targets 118 may be configured for integration with the inspection system 100, where the stage 110 may be configured to secure both runtime samples and at least one of the plurality of the one or more diagnostic targets 118. The inspection system 100 may be configured to generate diagnostic measurements using the qualified diagnostic targets, enabling runtime diagnostics and system calibration during inspection operations. In some cases, the diagnostic sample 1008 may be an extreme ultraviolet blank, and the resulting diagnostic targets may be configured for use with EUV reticle inspection systems such as actinic patterned mask inspection tools.

The system may include a packaging tool configured to package qualified diagnostic targets that meet the established quality metrics, ensuring proper protection and handling during storage and transportation. The packaging tool may be configured to maintain the cleanliness and integrity of the diagnostic targets while providing appropriate identification and traceability information for each packaged unit. This integrated manufacturing approach may enable the production of high-quality diagnostic targets with consistent performance characteristics, supporting reliable runtime diagnostics across various process tool applications.

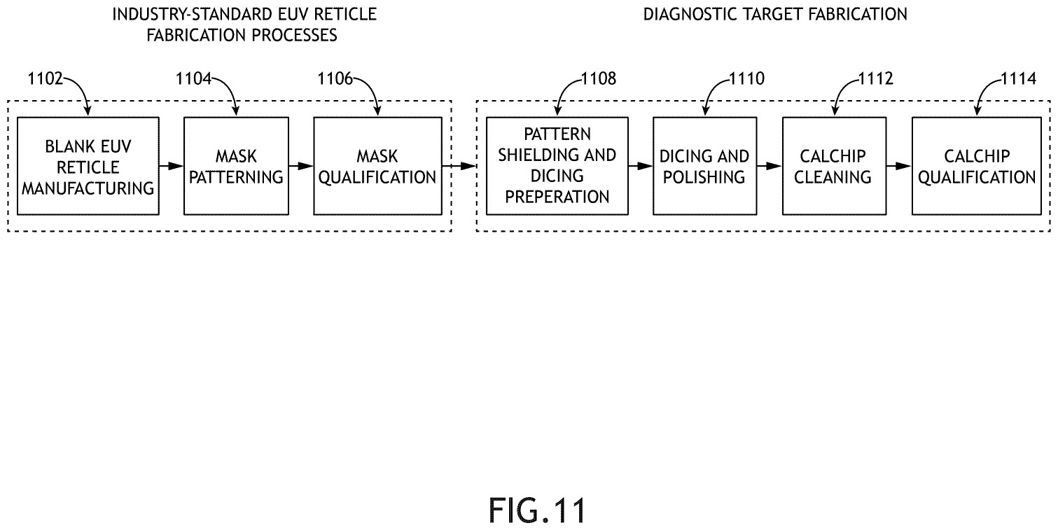

Referring now to FIG. 11, the fabrication of one or more diagnostic targets 118 by dicing a high-quality diagnostic sample is described. In particular, FIG. 11 describes a non-limiting example of one or more diagnostic targets 118 designed to provide diagnostics of an EUV reticle inspection tool.

FIG. 11 illustrates a flowchart showing a process that includes industry-standard EUV reticle fabrication processes and diagnostic target fabrication, in accordance with one or more embodiments of the present disclosure. The manufacturing process flow demonstrates how established EUV reticle fabrication infrastructure may be leveraged to create high-quality diagnostic targets 118 through a systematic approach that maintains the precision and reliability characteristics of production EUV masks.

In embodiments, a diagnostic sample may be generated through steps 1102-1106, which may include blank EUV reticle manufacturing, mask patterning, and mask qualification to create a high-quality patterned substrate with known performance characteristics. The diagnostic targets 118 may then be generated through steps 1108-1114, which may include pattern shielding and dicing preparation, dicing and polishing operations, cleaning, and qualification to produce individual calibration chips or bars from the diagnostic sample.

The process begins with a step 1102 that involves blank EUV reticle manufacturing, which may establish the foundational substrate and multilayer stack characteristics for the diagnostic sample. In some cases, the step 1102 may utilize the same substrate materials, multilayer deposition processes, and quality control procedures employed in production EUV reticle and/or mask manufacturing. The blank manufacturing process may include substrate preparation, multilayer stack deposition with alternating high and low refractive index materials, and initial quality verification to ensure the substrate meets specifications for EUV reflectivity and surface quality. The multilayer stack 702 deposited during the step 1102 may include multiple alternating layers designed to provide optimal reflectivity at EUV wavelengths, with each layer thickness precisely controlled to achieve the desired optical performance characteristics.

Following blank manufacturing, the process continues to a step 1104 for mask patterning, which may involve the application and patterning of absorber materials to create the diagnostic patterns on the diagnostic sample 1008. The step 1104 may utilize electron beam lithography, photolithography, or other patterning techniques to define the specific patterns designed for diagnostic measurements of process tools. In some cases, the patterning process may create multiple diagnostic target designs on a single diagnostic sample 1008, allowing for efficient production of numerous targets with different pattern characteristics. The step 1104 may also include etching processes to selectively remove portions of the absorber material and, in some cases, portions of the multilayer structure to create the desired pattern contrast and reflectivity characteristics for diagnostic measurements. The blank may include any combination of multilayer features and absorber features to achieve the desired optical properties for the diagnostic targets.

The process then proceeds to a step 1106 for mask qualification (e.g., quality control), which may involve comprehensive inspection and measurement of the patterned sample to verify pattern fidelity, dimensional accuracy, and defect levels. The step 1106 may utilize scanning electron microscopy, optical inspection tools, and other metrology equipment to assess the quality of the patterned structures before proceeding to diagnostic target fabrication. In some cases, the qualification process may include measurements of critical dimensions, pattern placement accuracy, and surface contamination levels to ensure the patterned sample meets the specifications for subsequent dicing operations. The step 1106 may also involve EUV reflectivity measurements to verify that the patterned areas provide the expected optical performance characteristics for diagnostic applications.

The diagnostic target fabrication phase begins with a step 1108 for pattern shielding and dicing preparation, which may involve applying protective layers to the patterned areas and preparing the diagnostic sample 1008 for precision cutting operations. The step 1108 may include the application of protective coatings to prevent damage to the absorber layer 704 and multilayer stack 702 during subsequent dicing operations. In some cases, the step 1108 may also involve the creation of fiducial marks 1402 or alignment features to guide the dicing process and ensure accurate positioning of cut lines relative to the patterned areas. The preparation process may include cleaning operations to remove particles and contaminants that could interfere with the dicing process or compromise the quality of the resulting diagnostic targets 118.

Following preparation, the process continues to a step 1110 for dicing and polishing operations, which may involve precision cutting of the diagnostic sample 1008 into individual diagnostic targets 118 and subsequent surface finishing. The step 1110 may utilize blade dicing, laser dicing, or other cutting techniques to separate the diagnostic targets while maintaining dimensional accuracy and minimizing damage to the patterned areas. In some cases, the dicing process may be followed by polishing operations to achieve specified surface roughness and edge quality requirements for the diagnostic targets 118. The step 1110 may also include chamfering operations to create the chamfered edges 306 that facilitate handling and installation of the diagnostic targets in inspection systems.

The process then proceeds to a step 1112 for CalChip (e.g., a diagnostic target 118) cleaning, which may involve removal of particles, contaminants, and residues introduced during the dicing and polishing operations. The step 1112 may utilize chemical cleaning processes, ultrasonic cleaning, or other techniques to achieve the molecular cleanliness requirements for EUV applications. In some cases, the cleaning process may include multiple stages with different cleaning chemistries to address various types of contamination while maintaining the integrity of the patterned structures.

The manufacturing process concludes with a step 1114 for CalChip qualification (e.g., quality control), which may involve comprehensive testing and inspection of the individual diagnostic targets 118 to verify their performance characteristics and compliance with specifications. The step 1114 may include dimensional measurements, particle contamination assessment, pattern fidelity verification, and molecular cleanliness testing using techniques such as gas chromatography-mass spectrometry. In some cases, the qualification process may utilize specialized inspection equipment with adaptors configured to accommodate the smaller size of the diagnostic targets 118 compared to full-size EUV masks. The step 1114 may also include functional testing to verify that the diagnostic targets provide the expected measurement capabilities for runtime diagnostics applications, ensuring that each qualified target meets the performance requirements for accurate system calibration and drift monitoring.

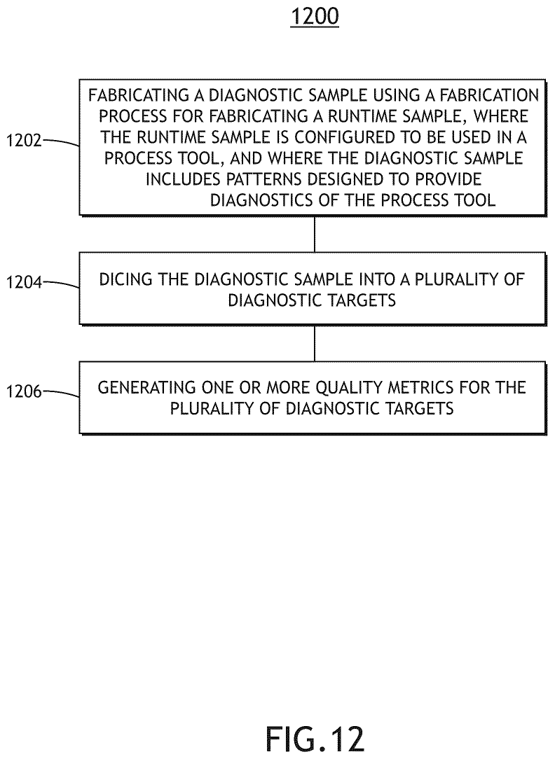

Referring now to FIG. 12, a method 1200 for manufacturing diagnostic targets 118 is described in greater detail, in accordance with one or more embodiments of the present disclosure. As described previously herein, diagnostic targets 118 may be fabricated for a wide variety of applications including, but not limited to, inspection, metrology, or lithography. In this way, the example described in FIG. 11 is merely an illustration and should not be interpreted as limiting the scope of the present disclosure.

FIG. 12 illustrates a flowchart of a method 1200 for manufacturing diagnostic targets, in accordance with one or more embodiments of the present disclosure. The method 1200 may provide a systematic approach for producing high-quality diagnostic targets 118 that may be configured for use in various process tools including inspection tools, metrology tools, and lithography tools. The method 1200 may leverage established fabrication processes to create diagnostic samples that may subsequently be diced into individual diagnostic targets 118 with well-defined performance characteristics suitable for providing diagnostics of a process tool. In some cases, the method 1200 may enable the production of diagnostic targets 118 with known optical, mechanical, and chemical properties that may facilitate accurate runtime diagnostics and system calibration operations.

The method 1200 includes a step 1202 of fabricating a diagnostic sample using a fabrication process for fabricating a runtime sample, wherein the runtime sample may be configured to be used in a process tool, wherein the diagnostic sample includes patterns designed to provide diagnostics of the process tool. In some cases, the step 1202 may utilize the same or suitably similar fabrication infrastructure, materials, and process parameters employed for manufacturing production samples, thereby ensuring that the diagnostic sample maintains the same quality standards and performance characteristics as runtime samples. The fabrication process may include substrate preparation, layer deposition, pattern transfer, and/or etching operations that may create multiple diagnostic target designs on a single diagnostic sample (e.g., calbar designs, calchip designs, or the like). The patterns created during the step 1202 may be configured to enable measurement of one or more imaging metrics of a process tool (e.g., the inspection system 100, any type of inspection tool, a metrology tool, a lithography tool, or the like) including at least one of illumination pupil characteristics, focus characteristics, or wavefront error. In some cases, the patterns may include test structures suitable for monitoring drift of at least one of the one or more imaging metrics over time during process tool operation.

The diagnostic sample fabricated in the step 1202 may include various material configurations depending on the intended application. In some cases, the diagnostic sample may be an extreme ultraviolet (EUV) blank, wherein the process tool may be an EUV reticle inspection system such as an actinic patterned mask inspection system. When fabricating patterns on the EUV blank to form the diagnostic sample, the process may comply with standards for fabricating EUV reticles, including the use of industry-standard substrate materials, multilayer stack 702 deposition processes, and absorber layer 704 patterning techniques. The EUV blank may include an EUV reticle blank with the same substrate layer 700, multilayer stack 702, and absorber layer 704 configurations used in production EUV masks, but may be patterned with different designs suitable for use as one or more diagnostic targets 118. In some cases, fabricating the diagnostic sample using the fabrication process used for fabricating the runtime sample may include fabricating patterned areas surrounded by margins, wherein dicing the diagnostic sample into the plurality of diagnostic targets may include dicing the diagnostic sample in the margins to separate individual targets while preserving pattern integrity.

The method 1200 may include a step 1204 of dicing the diagnostic sample into a plurality of diagnostic targets 118. The step 1204 may involve precision cutting operations that may separate the diagnostic sample into individual diagnostic targets 118 while maintaining dimensional accuracy and pattern fidelity. In some cases, dicing the diagnostic sample may include at least one of blade dicing or laser dicing, with the selection of dicing technique depending on the material properties of the diagnostic sample and the dimensional requirements of the resulting diagnostic targets 118. The step 1204 may utilize fiducial marks 1402 to guide dicing alignment, ensuring accurate positioning of cut lines relative to the patterned areas. The plurality of diagnostic targets 118 produced by the step 1204 may have at least two sizes, allowing for different applications or measurement requirements within the same process tool or across different process tool configurations.

The dicing process in the step 1204 may be configured to produce diagnostic targets 118 in various forms depending on the intended application. In some cases, the plurality of diagnostic targets 118 may include calibration chips 300 that may be dimensioned for step access from any swath location during inspection operations. In other cases, the plurality of diagnostic targets 118 may include calibration bars 400 that may extend along a substantial length to enable contiguous swath access during inspection processes. The diagnostic sample may include a substrate with one or more layers, wherein at least a portion of the one or more layers may be stripped in the margins to facilitate the dicing process and provide appropriate edge characteristics for the resulting diagnostic targets 118. In some cases, the margins may include black border trenches surrounding the patterned areas, which may provide mechanical protection for the sensitive patterned regions during the dicing operations.

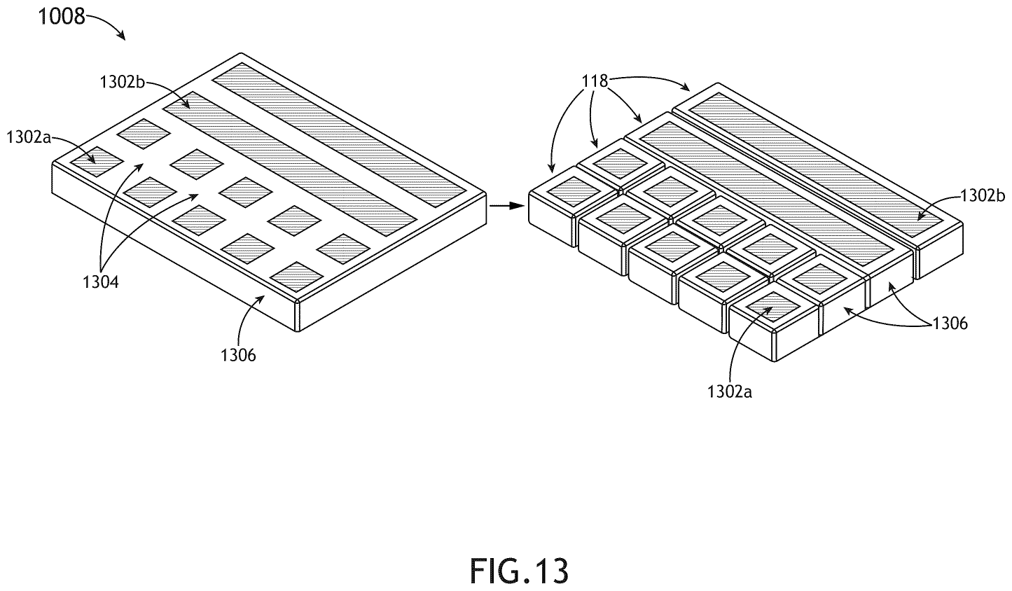

Referring now to FIG. 13, in some embodiments, multiple types or designs of diagnostic targets 118 may be fabricated from a single diagnostic sample. FIG. 13 illustrates two views of a diagnostic sample 1008 showing a dicing layout configuration, in accordance with one or more embodiments of the present disclosure. The diagnostic sample 1008 may be configured to enable efficient production of multiple diagnostic targets 118 (e.g., calchips, calbars, or the like) from a single fabricated substrate, providing a cost-effective approach for manufacturing diagnostic targets with consistent quality characteristics. The diagnostic sample 1008 may include multiple patterned areas arranged in a systematic layout that facilitates precision dicing operations while maintaining the integrity of the diagnostic patterns. In some cases, the diagnostic sample 1008 may be fabricated using the same processes employed for manufacturing runtime samples, ensuring that the resulting diagnostic targets 118 maintain the performance characteristics needed for accurate process tool diagnostics.

The left view of FIG. 13 shows the diagnostic sample 1008 having multiple patterned areas 1302a, 1302b arranged on a substrate 1306. The patterned areas 1302a, 1302b may be positioned in a grid-like arrangement that maximizes the utilization of the substrate 1306 surface area while providing adequate spacing for dicing operations. In some cases, a patterned area 1302a may have different dimensions (or designs of patterned features) than a patterned area 1302b, allowing for the production of diagnostic targets 118 with varying sizes and pattern configurations from the same diagnostic sample 1008. The substrate 1306 may include the same materials used in production samples, such as low thermal expansion glass for optical applications or specialized substrates for EUV applications. The arrangement of the patterned areas 1302a, 1302b on the substrate 1306 may be optimized to accommodate the specific requirements of different diagnostic target applications while maintaining manufacturing efficiency.

The patterned areas 1302a, 1302b may be separated by margins 1304 that provide the necessary spacing for dicing operations. A margin 1304 may be dimensioned to accommodate the material removal associated with the dicing process while ensuring that the cutting operations do not damage the adjacent patterned areas 1302a, 1302b. In some cases, the margins 1304 may include black border trenches surrounding the patterned areas 1302a, 1302b, which may provide mechanical protection for the sensitive pattern regions during dicing and handling operations. The margins 1304 may also serve as alignment references for the dicing equipment, facilitating accurate positioning of cut lines relative to the patterned areas 1302a, 1302b. The width of the margins 1304 may be determined based on the precision capabilities of the dicing system 1004 and the dimensional tolerances required for the resulting diagnostic targets 118.

The right view of FIG. 13 demonstrates how the diagnostic sample 1008 may be diced to form the one or more diagnostic targets 118. The dicing process may involve precision cutting operations that separate individual diagnostic targets 118 from the diagnostic sample 1008 while preserving the pattern fidelity and dimensional accuracy of each target. In some cases, the diagnostic targets 118 may include the patterned areas 1302a, 1302b and portions of the substrate 1306, with each target maintaining the structural integrity needed for installation and operation in process tools. The dicing operations may be performed in the margins 1304, ensuring that the cutting process does not compromise the quality of the patterned areas 1302a, 1302b. The resulting diagnostic targets 118 may include calibration chips 300 or calibration bars 400, depending on the specific pattern designs and dimensional requirements established during the fabrication of the diagnostic sample 1008.

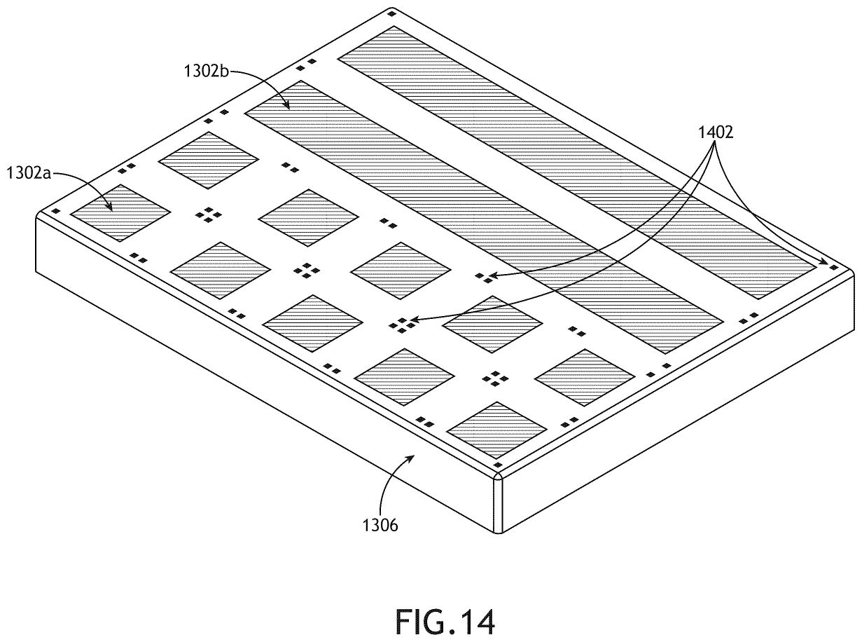

Referring to FIG. 14, the implementation of fiducial marks 1402 for guiding dicing alignment operations is described in greater detail. FIG. 14 illustrates an isometric view of a diagnostic target layout, in accordance with one or more embodiments of the present disclosure. The fiducial marks 1402 may be positioned along the perimeter of the diagnostic sample 1008 to provide precise alignment references for the dicing system 1004 during cutting operations. In some cases, the fiducial marks 1402 may be strategically placed to enable accurate positioning of cut lines relative to the patterned areas while maintaining the integrity of the diagnostic patterns throughout the dicing process. The systematic placement of the fiducial marks 1402 may facilitate automated dicing operations by providing machine-readable alignment features that can be detected by optical or mechanical alignment systems integrated within the dicing system 1004.

The fiducial marks 1402 may be created using the same fabrication processes employed for patterning the diagnostic areas, ensuring consistent quality and dimensional accuracy across all alignment features. In some cases, the fiducial marks 1402 may be formed using black bordering 308 processes that create high-contrast features against the substrate 1306 background, enabling reliable detection by alignment systems during dicing operations. The contrast between the highly reflective multilayer stack 702 areas and the black bordering 308 regions may provide the optical differentiation needed for precise alignment measurements. The fiducial marks 1402 may be positioned outside of the physical boundaries of the individual one or more diagnostic targets 118, allowing the marks to be removed during the dicing process while serving their alignment function throughout the cutting operations.

The shape, size, and form factor of the fiducial marks 1402 may be customized depending on the specific dimensions of the one or more diagnostic targets 118 and the alignment method employed by the dicing system 1004. In some cases, the fiducial marks 1402 may include geometric patterns such as crosses, squares, or circular features that can be easily recognized by machine vision systems integrated within the dicing equipment. The dimensional characteristics of the fiducial marks 1402 may be optimized to provide adequate signal-to-noise ratio for detection systems while minimizing the substrate 1306 area consumed by alignment features. The positioning accuracy of the fiducial marks 1402 relative to the patterned areas 1302a may be controlled during the fabrication process to ensure that the alignment references provide the precision needed for accurate dicing operations.

The implementation of the fiducial marks 1402 may enable the dicing system 1004 to achieve dimensional tolerances that maintain the quality and performance characteristics of the resulting one or more diagnostic targets 118. In some cases, the alignment system may utilize the fiducial marks 1402 to compensate for substrate 1306 positioning variations, thermal expansion effects, or mechanical distortions that could otherwise compromise the accuracy of the dicing operations. The fiducial marks 1402 may be designed to accommodate different types of alignment systems, including optical detection systems that rely on contrast measurements and mechanical probing systems that detect surface features through physical contact. The versatility of the fiducial mark 1402 design may allow the same diagnostic sample 1008 layout to be processed using different dicing system 1004 configurations while maintaining consistent alignment accuracy across various manufacturing setups.

The fabrication approaches illustrated in FIGS. 13-14 may enable the production of diagnostic targets 118 with known and predictable performance characteristics by leveraging established fabrication processes for creating the diagnostic sample 1008. The systematic layout of patterned areas 1302a, 1302b surrounded by margins 1304 may facilitate efficient dicing operations while maintaining the quality standards needed for accurate process tool diagnostics. In some cases, the diagnostic sample 1008 may be designed to accommodate specific requirements for different types of diagnostic targets, such as calibration chips 300 for step access applications or calibration bars 400 for contiguous swath access applications. The dicing configuration may allow for the simultaneous production of multiple diagnostic target types from a single fabrication run, providing manufacturing efficiency while ensuring consistent quality across all produced targets.

Referring again to FIG. 12, the method 1200 may include a step 1206 of generating one or more quality metrics for the plurality of diagnostic targets. The step 1206 may involve comprehensive inspection and measurement of the diced diagnostic targets 118 to verify their compliance with specifications and performance requirements. The one or more quality metrics may include at least one of dimensional tolerances, particle contamination limits, pattern fidelity requirements, and molecular cleanliness requirements that may be established based on the intended application and process tool requirements. In some cases, the step 1206 may utilize various measurement and inspection techniques including scanning electron microscopy for pattern fidelity qualification, particle detection systems for contamination analysis, and gas chromatography-mass spectrometry for molecular cleanliness testing. The qualification process may employ specialized inspection equipment with adaptors configured to accommodate the smaller size of the diagnostic targets 118 compared to full-size production samples.

Although not shown, the method 1200 may include a step of filtering out any of the plurality of diagnostic targets 118 that do not meet selected quality standards. This step may involve comparing the quality metrics generated in the step 1206 against predetermined acceptance criteria to identify diagnostic targets 118 that may be suitable for deployment in process tools. In some cases, the filtering process may be automated using the controller 122 with the one or more processors 124 configured to execute program instructions for evaluating quality metrics and making acceptance decisions. The step may ensure that only diagnostic targets 118 with verified performance characteristics may proceed to subsequent packaging and deployment operations, thereby maintaining the reliability and accuracy of runtime diagnostics measurements.

The method 1200 may further include applying one or more protection layers to at least a portion of the patterns prior to dicing the diagnostic sample into the plurality of diagnostic targets 118. These protection layers may shield sensitive patterned areas from damage during the dicing operations, particularly when cutting through multilayer stack 702 and absorber layer 704 structures. In some cases, the method 1200 may further include removing at least a portion of the one or more protection layers from at least some of the plurality of diagnostic targets 118 after dicing to expose the functional surfaces for diagnostic measurements. The method 1200 may also include post-dicing processing of the plurality of diagnostic targets 118, wherein the post-dicing processing may include at least one of polishing diced surfaces, chamfering edges, or cleaning the plurality of diagnostic targets 118 to achieve specified surface quality and contamination levels.

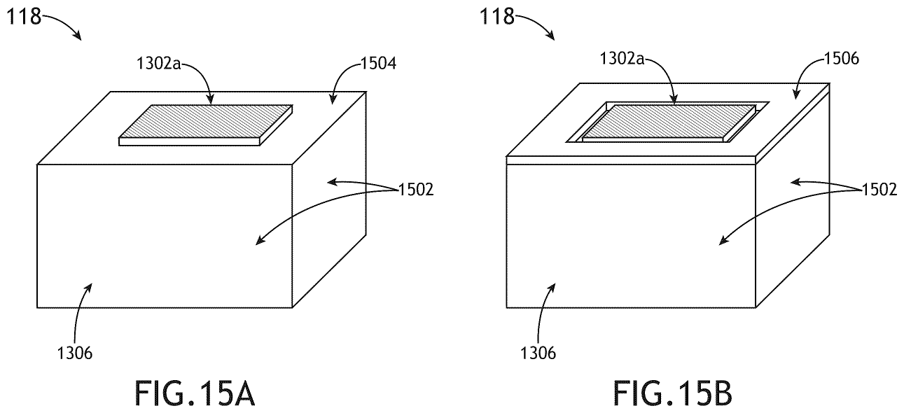

FIGS. 15A and 15B illustrate cross-sectional views of diagnostic targets, in accordance with one or more embodiments of the present disclosure. The cross-sectional configurations shown in FIGS. 15A and 15B may demonstrate different approaches for fabricating diagnostic targets 118.

In FIGS. 15A-15B, a patterned area 1302a may be disposed on the substrate 1306, containing the diagnostic patterns designed to provide measurements of process tool performance parameters. For example, the patterned area 1302a may include multilayer stack and/the absorber layers in any suitable patterns such as, but not limited to, those described previously. In some cases, the patterned area 1302 has specific pattern geometries designed for measuring imaging metrics such as illumination pupil characteristics, focus characteristics, or wavefront error. Sidewalls 1502 may extend along the edges of the diagnostic target after dicing. These sidewalls 1502 may in some cases be polished (e.g., in a post-dicing step).

The configuration shown in FIG. 15A may include a stripped area 1504 that surrounds the patterned area 1302a. The stripped area 1504 may represent regions where at least a portion of one or more layers have been removed from the substrate 1306, creating exposed substrate surfaces adjacent to the patterned regions. The stripped area 1504 may facilitate the dicing process by providing clear demarcation between the sensitive patterned regions and the areas designated for cutting operations. The exposed substrate material in the stripped area 1504 may also provide mechanical stability and handling surfaces that do not compromise the optical performance of the patterned area 1302a.

The configuration shown in FIG. 15B may include a protective layer 1506 that may be provided around the patterned area 1302a. The protective layer 1506 may represent a different approach to edge treatment compared to the stripped area 1504 shown in FIG. 15A. In some cases, the protective layer 1506 may include a coating or film applied to the surface regions surrounding the patterned area 1302a to provide protection during handling, storage, or operation of the diagnostic target. The protective layer 1506 may be applied during post-dicing processing operations, which may include polishing diced surfaces, chamfering edges, or cleaning the plurality of diagnostic targets 118. The protective layer 1506 may serve to prevent contamination of the sensitive patterned regions while allowing the diagnostic target to maintain the optical and mechanical properties needed for accurate measurements. The choice between the stripped area 1504 configuration shown in FIG. 15A and the protective layer 1506 configuration shown in FIG. 15B may depend on the specific application requirements and the operating environment of the process tool.

Both cross-sectional configurations shown in FIGS. 15A and 15B may accommodate the chamfered edges 306 described previously, which may be created during post-dicing processing operations to facilitate handling and installation of the diagnostic targets. The sidewalls 1502 may be processed to achieve specified surface roughness and dimensional tolerances that enable proper mounting and alignment within process tools such as the inspection system 100. In some cases, the sidewalls 1502 may be polished or otherwise treated to remove damage or irregularities introduced during the dicing operations, ensuring that the diagnostic targets maintain the mechanical precision needed for accurate positioning on the stage 110. The post-dicing processing operations may also include cleaning procedures to remove particles and contaminants that could interfere with the diagnostic measurements or compromise the performance of the process tool.

The method 1200 may further include placing at least one of the plurality of diagnostic targets 118 proximate to the runtime sample in the process tool and generating diagnostic measurements of the process tool using the at least one of the plurality of diagnostic targets 118. In some cases, the diagnostic measurements may be runtime diagnostics (RTD) that may be performed during process tool operation to monitor system performance and detect drift in imaging metrics. The process tool may include at least one of an inspection tool, a metrology tool, or a lithography tool, with the diagnostic targets 118 configured to provide appropriate measurement capabilities for each tool type. The method 1200 may further include packaging qualified diagnostic targets that meet the one or more quality metrics, ensuring proper protection and identification during storage and transportation to end-use applications. The embodiments and enabling technologies described in the context of the inspection system 100, fabrication system 1002, dicing system 1004, and qualification system 1006 described herein may be interpreted to extend to the method 1200. However, the method 1200 may not be limited to the architecture of any systems described herein.

The method 1200 may further include establishing a high yield manufacturing process that may be verified through comprehensive EUV/DUV chip inspection protocols. In some embodiments, the high yield may be achieved by optimizing the dicing parameters, protective measures, and handling procedures to minimize defects and maintain pattern integrity across the entire production run. The yield verification may involve systematic inspection of representative samples from each production batch using EUV or DUV inspection systems to assess dimensional accuracy, pattern fidelity, and surface quality. In some cases, the inspection protocols may include automated defect detection algorithms that can identify and classify various types of manufacturing defects, enabling continuous process improvement and yield optimization. The high yield manufacturing approach may ensure that a substantial percentage of the diced diagnostic targets 118 meet the stringent quality requirements for process tool calibration applications.

In some embodiments, the method 1200 may include establishing cleanliness requirements for individual diagnostic targets 118 that may be verified through particle detection systems capable of identifying contaminants as small as 30 nm in diameter. The cleanliness verification may be performed using EUV or DUV inspection tools equipped with high-resolution particle detection capabilities that can scan the entire surface of each diagnostic target. The inspection process may differentiate between different regions of the diagnostic targets, applying more stringent cleanliness standards to the patterned areas while allowing for relaxed requirements on non-critical surfaces such as sidewalls 1502 or mounting areas. In some cases, the particle inspection may be integrated with pattern damage assessment to provide comprehensive quality evaluation in a single inspection pass.

The method 1200 may also incorporate damage-free verification protocols that confirm the integrity of EUV patterns and multilayer stack 702 structures following the application and removal of protective resists or tapes. In some embodiments, the verification process may utilize EUV or DUV inspection systems to detect any alterations, contamination, or structural damage that may have occurred during the shielding and dicing operations. The inspection may assess the reflectivity characteristics, pattern edge quality, and multilayer stack uniformity to ensure that the protective measures do not compromise the optical performance of the diagnostic targets 118. In some cases, the damage verification may include comparative analysis between pre-dicing and post-dicing inspection results to quantify any changes in pattern quality or surface characteristics.

To enhance manufacturing throughput and efficiency, the method 1200 may include developing multi-chip adaptors that enable simultaneous inspection of several diagnostic targets 118 in each inspection session. In some embodiments, these adaptors may be configured to accommodate different sizes and shapes of diagnostic targets, providing flexibility for custom applications while maintaining inspection accuracy and repeatability. The multi-chip inspection capability may significantly reduce the time required for quality verification, enabling higher production volumes and faster turnaround times for diagnostic target manufacturing.

In some aspects, the method 1200 may be adapted to create diagnostic targets 118 with custom dimensions and geometries tailored to specific process tool requirements. The customization capability may include producing specialized calibration chips 300 for particular measurement algorithms or calibration bars 400 with non-standard aspect ratios for unique inspection configurations. In some cases, the dicing system 1004 may be configured with programmable cutting patterns that can accommodate various target shapes, including rectangular, square, or other geometric configurations as needed for specific applications. The custom sizing capability may allow the manufacturing process to address diverse application needs while maintaining the same high-quality fabrication standards and verification procedures established for standard diagnostic target configurations.

In some embodiments, the method 1200 may include applying protective resists developed and used by the semiconductor industry that are compatible with EUV masks to protect patterns against particles and chemical contaminants during dicing and cleaning processes. These industry-standard resists may provide a temporary protective barrier over sensitive patterned areas, preventing damage from cutting debris, cleaning chemicals, or airborne contaminants that could compromise pattern fidelity. The protective resists may be selected based on their proven compatibility with EUV multilayer stack 702 and absorber layer 704 materials, ensuring that the application and subsequent removal processes do not introduce contamination or structural damage to the diagnostic patterns. In some cases, the resist application may be performed using established semiconductor fabrication techniques such as spin coating, spray coating, or vapor deposition to achieve uniform coverage over the patterned areas 1302a.

In some embodiments, the method 1200 may include applying protective tapes developed and used by the semiconductor industry that are compatible with EUV masks to protect patterns against particles and chemical contaminants during dicing and cleaning processes. These specialized tapes may provide mechanical protection during handling and processing operations, shielding the diagnostic patterns from physical contact, particle deposition, and environmental contaminants. The protective tapes may be engineered with adhesive properties that allow secure attachment to the diagnostic sample 1008 while enabling clean removal without leaving residues or causing damage to the underlying patterns. In some cases, the tapes may be applied to cover the entire patterned surface or may be selectively applied to specific regions based on the dicing layout and processing requirements.

In some embodiments, the method 1200 may include the simultaneous use of both protective resists and protective tapes to provide comprehensive protection during dicing and cleaning operations. The combined protection approach may utilize the resist to provide chemical barrier properties against cleaning solvents and fine particle contamination, while the tape may provide mechanical shielding and handling protection during physical processing steps. In some cases, the resist may be applied first to create a conformal coating over the patterned features, followed by tape application to provide additional mechanical protection during dicing operations. The dual protection system may be particularly beneficial for complex dicing processes that involve multiple processing steps or extended handling periods where the diagnostic targets 118 may be exposed to various contamination sources.

In some embodiments, the method 1200 may include developing specialized adaptors to enable loading of calibration chips 300 into existing mask inspection tools. These adaptors may be configured to accommodate the smaller dimensions of the diagnostic targets 118 compared to standard EUV masks while maintaining proper mechanical registration and optical alignment within the inspection system. The adaptors may interface with existing stage mechanisms and clamping systems, allowing the diagnostic targets 118 to be positioned accurately within the inspection field of view without requiring modifications to the primary inspection tool hardware. In some cases, the adaptors may include precision alignment features, vacuum clamping systems, or mechanical fixtures that ensure repeatable positioning of the diagnostic targets 118 during inspection operations. The adaptor design may enable the use of established inspection and qualification equipment for evaluating the diagnostic targets 118, providing consistent measurement capabilities and leveraging existing calibration procedures.

Any of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

Additional aspects of one or more diagnostic targets 118 are now described.

Actinic patterned mask inspection (APMI) or actinic blank inspection (ABI) tools are designed to achieve and maintain extreme imaging resolution and stability in order to reliably and repeatably detect patterned mask or blank reticle defects. The stringent detection sensitivity and high inspection throughput, as required by the semiconductor manufacturing industry, mandates periodic, automated, fast, and accurate tool calibrations during inspection.

Some of the key inline metrology metrics rely on engineered high-fidelity EUV calibration targets to monitor health of the inspection system and characterize the illumination condition and imaging quality. The information from this inline metrology can utilized in different ways, for example be provided to the inspection processing algorithms to account for the system variation from nominal condition, be fed back to the relevant tool actuators to correct the undesired system drifts, or recommend follow up maintenances or calibration processes. In order for the calibration process to be a proper representation of the inspection condition: a) The target should be of excellent quality, and preferably comparable to cutting edge industry level EUV mask standards. b) the calibration target should access exact field of view that is used during the mask inspection and c) within a very short time gap from the ongoing inspection. Hence, the target should be at the vicinity of the mask under inspection for quick access, maybe by a simple extra stage travel during inspection.

While a conventional EUV mask can satisfy the first two properties (a and b) above, it is not proper to gratify the 3^{rd} need (c). Due to limited real-estate and engineering complexity, it is very challenging and cost ineffective to include a full-size patterned EUV mask as the calibration target next to the mask under inspection. A miniaturized EUV mask with a substrate material, EUV stack quality, fine EUV features on par with the industrially approved EUV masks can be an ideal solution to this problem. Therefore, there is a growing need for such a miniaturized EUV reticle with identical or close to EUV specs to industrial EUV masks. We refer to such miniaturize EUV masks as diagnostic targets. Currently no such solution exists, or the manufacturing process is not stable and reliable for high volume industrial production. To address this need, we are disclosing an invention that allows us to manufacture high quality diagnostic targets reliably, at high quantities, and cost effectively.

For a diagnostic target manufacturing to be versatile and successful in addressing APMI and ABI calibration needs it should meet several major requirements.

Sufficient EUV reflectivity: For an EUV diagnostic target it is desirable to offer high EUV reflectivity which is ideally matching or comparable to the EUV reflectivity of conventional reticles. This warrants the target to include multilayer stack identical or similar to mainstream EUV reticle industry. Although, for certain calibrations a non-standard EUV stack or a non-EUV target can be emulated, majority of calibration steps rely on sufficient EUV reflectivity.

Material and quality compatible with EUV industry: For some applications not only high EUV reflectivity is needed, but also the stack specifications need to match or be close to industry blank manufacturing specifications. An EUV stack that is not a close representative of industry standards may result in significantly different properties (e.g. EUV angular and spectral reflectivity profile or molecular/atomic compositions) than a customer mask and may render tool calibrations irrelevant to the inspection task. The quality of substrate (like roughness and flatness) can also play an important role in the quality of calibrations. For certain applications it an exact match to the industry EUV material will not be necessary; however, it is challenging to achieve reliable and repeatable calibration if the EUV stack quality is far from the industrial EUV reticles. For these reasons, it is ideal for the EUV target to use same or very similar materials and manufacturing process as the well-established EUV mask production.

High fidelity and fine EUV features: Fine imaging resolution of an APMI tool may demand for fine EUV targets for some of the metrology steps. Such fine features may be precisely engineered and well characterized for excellent calibration. To allow consistent calibration across different diagnostic targets and APMI tools, the EUV patterns may have great patterning uniformity and reproducibility. Excessive patterning imperfections, like reflectivity nonuniformity, ML roughness, or pattern infidelity can significantly degrade the calibration accuracy and repeatability. Such fine patterns with high fidelity demand a patterning quality is offered by the leading-edge industry level EUV mask making technologies.

EUV industry level cleanliness: EUV tools are very sensitive to molecular and particle contamination. Molecular contamination is a large risk for EUV tools. Since diagnostic targets might be used at the vicinity of EUV retiles during inspection, extremely low molecular contamination becomes a critical aspect of diagnostic target manufacturing process. If there are additional cleanliness demanded by the APMI tool, the diagnostic target manufacturing process should also respect tool specific requirements.

Size flexibility and adaptability: Diagnostic target dimension requirements can vary for tools from various vendors or different tool generations. These dimension requirements might root in the stage mass and inertia limitation, stage travel range, available real-estate, lifetime, mechanical registration, and/or applications of the diagnostic target. Therefore, the diagnostic target manufacturing technology should not be restricted to a particular lateral dimension. Instead, it may offer sufficient flexibility to allow production of diagnostic targets at various lateral dimensions. This is contrasting with the existing mask manufacture industry which relies on a unified dimensions during entire EUV mask lifecycle.

Qualification: The final diagnostic target product may go thru a set of qualification steps to ensure it meets all critical requirements, including: Diagnostic target dimensions: Despite the size flexibility, the diagnostic target dimensions might follow tight mechanical and dimensional tolerances as imposed by the hosting tool and expected application. Particle contamination: The diagnostic target should not pose a risk of cross contaminating the APMI tools or the reticles. The actual particle contamination requirements may vary depending on the tool, application, and location. Similarly, different areas of the diagnostic targets might tolerate different levels particle contaminations which should be considered during diagnostic target manufacturing process and qualification steps. Process specific requirements: depending on the diagnostic target manufacturing process, additional qualification steps might be necessary. Such requirements will be process specific and will vary depending on the manufacturing method.

Cost effective: To make this a universal and versatile solution attention to be paid to diagnostic target manufacturing cost. The ideal solution should not mandate prohibitively expensive novel equipment to or technology.

Industrial EUV mask manufacturing processes has found a resolution to stringent requirements on EUV reflectivity, EUV feature size, pattern fidelity, stack quality, substrate flatness, and cleanliness in some applications. However, the current EUV mask manufacturing infrastructure is limited to a very specific mask dimensions (152 mm×152 in×6.35 in) and cannot be readily used to manufacture miniaturized EUV masks of custom sizes.

Embodiments of the present disclosure propose a postproduction mask resizing process to address this problem. This approach utilizes the conventional EUV mask making infrastructure to create high fidelity EUV patterns. Then it slices the patterned mask to desired sizes by a special precision cutting mechanism and extracts the area of interest from the EUV mask. This process follow is presented in FIG. 1. This method enables non-standard miniaturized EUV mask manufacturing without demanding the development of a new specialized patterning technology. Furthermore, the proposed method is able to progress in parallel with the ever-advancing mask manufacturing industry and offer an EUV patterning quality on-par with the leading EUV mask manufacturing technology at each date.

Various embodiments of the present disclosure provide at least some of the following aspects.

Sufficient EUV reflectivity: by using industry blanks high EUV reflectivity can be attained. It may be important for the dicing process to protect the EUV stack from any damage or degradation and, hence, guarantee an EUV reflectivity on-par with the parent reticle. If a distinct reflectivity value, spectral or angular reflectivity profiles from the commercially available EUV industry is needed, this approach can be adapted to a special blank reticle with customized multilayer stack.

Material compatible with EUV industry: The diagnostic targets which will be manufactured using industry approved EUV blanks and EUV patterning process, can inherently satisfying this requirement. The dicing process may be designed in accordance with EUV mask manufacturing standards to warrant that the final diagnostic targets are in compliance with the EUV industry standards. During dicing the product should not be exposed to EUV incompatible substrates, or damaging processes like excessive heat, or mechanical stress, ideally. If any cleaning method is applied to the product, the process and the ingredients should follow EUV mask manufacturing standards and guidelines. If there are any deviations from the conventional mask manufacturing industry, the additional processed should be qualified independently or as a whole process.

High fidelity and fine EUV features: The existing industrial EUV patterning infrastructure enables realization of fine and high fidelity EUV patterns, as well as acceptable patterning uniformity and repeatability. This high fidelity is acceptable for most APMI tool calibrations. This approach allows transferring such patterning quality to diagnostic targets which are basically EUV masks with smaller than conventional EUV masks. With progression of EUV mask writing technology, it is expected that the feature sizes to shrink in future. The proposed method has the potential to adapt and accommodate future EUV features such as curvilinear patterns and phase shifting masks.

EUV industry level cleanliness: In this method the diagnostic targets are created by dicing an EUV masks, which inherently meet the industry level cleanliness requirements. Once the dicing procedure is designed in compliance with the EUV industry standards, the final diagnostic target cleanliness will be comparable to EUV industry requirements. Development of special tooling for diagnostic target handling may be desirable to minimize the risk of diagnostic target contamination during and/or post fabrication. Nonetheless, the molecular cleanliness of the final diagnostic targets can be verified using industry accepted cleanliness tests such as gas chromatography-mass spectrometry (GC-MS). This can be applied to a batch of witness diagnostic targets to qualify the process or can be used for all the final diagnostic target products. Certain APMI tools may have cleanliness requirements that are more stringent than the mask manufacturing process and set additional restrains on qualification process. The molecular cleanliness qualification process should be able to address such needs. Qualification of the diagnostic targets for particles adders is another often desirable step. The particle qualification process shall meet the sensitivity requirements as indicated by the APMI tool

Size flexibility and adaptability: Dicing by nature offers a wide diagnostic target size selection. Such flexibility is not offered with the previous industrial EUV mask patterning technologies. The systems and methods disclosed herein may be distinguished from traditional non-industrial EUV patterning methods such as those in research labs. The proposed technology can offer high-volume manufacturing of custom resized industrial quality EUV masks, while the existing methods are limited in production quantity, material, and/or pattern quality. While in the invented method the maximum diagnostic target size will be limited to the native mask dimensions, the smallest diagnostic target size will be limited by the dicing method. Nonetheless, it will still provide sufficient size range to support many of exiting and forthcoming industry needs. Once a new diagnostic target size is manufactured, some modification of the inspection, tooling, packaging, and mounting will be warranted to accommodate the new dimensions. However, this is will not dictated a fundamental limitation on the diagnostic target dimensions.

Qualification: Besides molecular cleanliness, the diced diagnostic targets may be qualified for diagnostic target dimensions: The final diagnostic target dimensions may be precisely measured and qualified against APMI tool requirements. A final dimensional report may consider qualification of all key of feature including diagnostic target physical dimensions, side wall angles, pattern alignment with respect to diagnostic target mechanical boundaries, chamfer size, or the like. Additional metrology might be necessary depending dicing process and tool specific requirements.

Particle contamination: Depending on the dicing mechanism, there can be a significant particle contamination risk. Even though the dicing method shall provide proper particle mitigation strategies to meet particle cleanliness requirements, the diagnostic targets maybe inspected for particles during qualification phase. The particle requirements can be region dependent. The EUV patterned area might have tighter particle requirements than the side wall or non-pattern surfaces. The particle inspection mechanism for each region should be selected I accordance with the qualification requirements. Diagnostic target inspection with an EUV mask inspector can be designed to also provide necessary particle detection sensitivity.

Pattern damage: It may be desirable to design the dicing process to pose minimum possible risk to the EUV patterns as well as important surfaces. The process may include applying proper protection layers to establish a reliable diagnostic target manufacturing yield. Absence of any disqualifying damage to the EUV pattern may be verified with proper inspections post dicing. It is possible that particle inspection and pattern damage inspection can share a common tool and metrology step.

While the pre-dicing inspection is to qualify the EUV mask prior to the dicing steps, the main goal of the post-dicing inspection is to detect any potential pattern alteration, damage, or contamination during the cutting and cleaning steps. In some cases, exiting EUV mask inspectors are designed for standard EUV reticle size. A special adaptor has been implemented that allows loading the manufactured diagnostic targets into a KLA Teron inspector. Die-to-Data Base inspection may be used to detect contaminations, potential damages to multilayer and absorber, and/or pattern imperfections simultaneously. Optimized settings may be used to detect small particles as malls as <50 nm. During a research and development phase the feedback from this tool allowed the dicing and cleaning process to be continuously tuned until acceptably low particle count could be achieved. During high volume manufacturing each individual diagnostic target is inspected and qualified for particle adders. The current adaptor is designed for pattern area inspection only.

Cost effective: The main HVM cost items for this diagnostic target production method are EUV reticle, EUV mask patterning, patterning qualification, dicing process, qualification steps, and final packaging. Among these items EUV reticle and EUV patterning are among the highest cost contributors. An advantage of the proposed method is the ability to rely on the established EUV mask patterning technology, and hence no additional patterning infra structure is needed. Moreover, it can provide multiple diagnostic targets from a single parent mask depending on the target diagnostic target dimensions In fact, the invented method is able to manufacture diagnostic targets of various sizes from one EUV reticle.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A method comprising:
fabricating a diagnostic sample using a fabrication process for fabricating a runtime sample, wherein the runtime sample is configured to be used in a process tool, wherein the diagnostic sample includes patterns designed to provide diagnostics of the process tool;
dicing the diagnostic sample into a plurality of diagnostic targets; and
generating one or more quality metrics for the plurality of diagnostic targets.

2. The method of claim 1, further comprising:
filtering out any of the plurality of diagnostic targets that do not meet selected quality standards.

3. The method of claim 1, further comprising:
placing at least one of the plurality of diagnostic targets proximate to the runtime sample in the process tool; and
generating diagnostic measurements of the process tool using the at least one of the plurality of diagnostic targets.

4. The method of claim 3, wherein the diagnostic measurements are runtime diagnostics (RTD).

5. The method of claim 1, wherein the diagnostic sample is an extreme ultraviolet (EUV) blank, wherein the process tool is an EUV reticle inspection system.

6. The method of claim 5, wherein fabricating the patterns on the EUV blank to form the diagnostic sample complies with standards for fabricating EUV reticles.

7. The method of claim 5, wherein the EUV blank comprises an EUV reticle blank.

8. The method of claim 5, wherein the EUV reticle inspection system comprises an actinic patterned mask inspection system.

9. The method of claim 1, further comprising:
applying one or more protection layers to at least a portion of the patterns prior to dicing the diagnostic sample into the plurality of diagnostic targets.

10. The method of claim 9, further comprising:
removing at least a portion of the one or more protection layers from at least some of the plurality of diagnostic targets after dicing.

11. The method of claim 1, wherein fabricating the diagnostic sample using the fabrication process used for fabricating the runtime sample comprises:
fabricating patterned areas surrounded by margins, wherein dicing the diagnostic sample into the plurality of diagnostic targets comprises dicing the diagnostic sample in the margins.

12. The method of claim 11, wherein the diagnostic sample comprises a substrate with one or more layers, wherein at least a portion of the one or more layers are stripped in the margins.

13. The method of claim 11, wherein the margins include black border trenches surrounding the patterned areas.

14. The method of claim 1, wherein the plurality of diagnostic targets comprise calibration chips.

15. The method of claim 1, wherein the plurality of diagnostic targets comprise calibration bars.

16. The method of claim 1, wherein dicing the diagnostic sample comprises at least one of blade dicing or laser dicing.

17. The method of claim 1, wherein dicing the diagnostic sample comprises using fiducial marks to guide dicing alignment.

18. The method of claim 1, further comprising post-dicing processing of the plurality of diagnostic targets, wherein the post-dicing processing comprises at least one of polishing diced surfaces, chamfering edges, or cleaning the plurality of diagnostic targets.

19. The method of claim 1, wherein the one or more quality metrics comprise:
at least one of dimensional tolerances, particle contamination limits, pattern fidelity requirements, and molecular cleanliness requirements.

20. The method of claim 1, wherein the plurality of diagnostic targets have at least two sizes.

21. The method of claim 1, further comprising packaging qualified diagnostic targets that meet the one or more quality metrics.

22. The method of claim 1, wherein the patterns are configured to enable measurement of one or more imaging metrics including at least one of illumination pupil characteristics, focus characteristics, or wavefront error of the process tool.

23. The method of claim 22, wherein the patterns comprise test structures for monitoring drift of at least one of the one or more imaging metrics.

24. The method of claim 22, wherein the process tool comprises:
at least one of an inspection tool, a metrology tool, or a lithography tool.

25. A system comprising:
a fabrication tool configured to fabricate patterns on a diagnostic sample using a fabrication process for fabricating a runtime sample, wherein the runtime sample is configured to be used in a process tool, wherein the diagnostic sample includes patterns designed to provide diagnostics of a process tool;
a dicing tool configured to dice the diagnostic sample into a plurality of diagnostic targets;
one or more qualification tools to generate one or more quality metrics for the plurality of diagnostic targets; and
the process tool including a stage configured to:
secure the runtime sample and at least one of the plurality of diagnostic targets; and
generate diagnostic measurements of the process tool using the at least one of the plurality of diagnostic targets.

26. The system of claim 25, further comprising:
a controller including one or more processors configured to execute program instructions causing the one or more processors to filter out any of the plurality of diagnostic targets that do not meet selected quality standards.

27. The system of claim 25, wherein the sample is an extreme ultraviolet (EUV) blank, wherein the process tool is an EUV reticle inspection system.

28. The system of claim 25, wherein the dicing tool comprises at least one of a blade dicing tool or a laser dicing tool.

29. The system of claim 25, further comprising one or more post-dicing processing tool configured to perform post-dicing processing of the diagnostic targets, wherein the post-dicing processing comprises at least one of polishing diced surfaces, chamfering edges, or cleaning the diagnostic targets.

30. The system of claim 25, wherein the one or more quality metrics comprise:
at least one of dimensional tolerances, particle contamination limits, pattern fidelity requirements, and molecular cleanliness requirements.

31. The system of claim 25, further comprising a packaging tool configured to package qualified diagnostic targets that meet the one or more quality metrics.
